(19) United States
(12) Patent Application Publication
(10) Pub. No.: US 2025/0212584 A1
(43) Pub. Date: Jun. 26, 2025

(54) DISPLAY DEVICE

(71) Applicant: Samsung Display Co., LTD., Yongin-si (KR)

(72) Inventor: Chan Woo JOO, Yongin-si (KR)

(21) Appl. No.: 18/971,326

(22) Filed: Dec. 6, 2024

(30) Foreign Application Priority Data
Dec. 20, 2023 (KR) 10-2023-0187307

(51) Int. Cl. H10H 29/49; H10H 20/816; H10H 29/80

(52) U.S. Cl. CPC H10H 29/49; H10H 20/816; H10H 29/8325

(57) ABSTRACT

A display device is provided. The display device includes a substrate having a pixel electrode, a light emitting element on the pixel electrode, and a connection electrode layer including a plurality of connection electrodes between the pixel electrode and the light emitting element, the plurality of connection electrodes being spaced from each other.

### CROSS-REFERENCE TO RELATED APPLICATION

The present application claims priority to and the benefit of Korean Patent Application No. 10-2023-0187307, filed on Dec. 20, 2023, in the Korean Intellectual Property Office, the entire disclosure of which is incorporated by reference herein.

### BACKGROUND

### 1. Field

The present disclosure relates to a display device.

### 2. Description of the Related Art

The importance of display devices is increasing with the development of multimedia. In response to this, various types of display devices such as organic light emitting diode (OLED) displays and liquid crystal displays (LCD) are being used.

A display device that displays images includes a display panel such as an organic light emitting display panel or a liquid crystal display panel. Among them, the light emitting display panel may include a light emitting element, for example, a light emitting diode (LED), an organic light emitting diode (OLED) using an organic material as a light emitting material, an inorganic light emitting diode using an inorganic material as a light emitting material, and/or the like.

Aspects and features of embodiments of the present disclosure are to provide a display device with improved bonding yield between a light emitting element and a pixel electrode.

However, aspects of the present disclosure are not restricted to the one set forth herein. The above and other aspects of the present disclosure will become more apparent to a person of ordinary skill in the art from the present disclosure.

### SUMMARY

According to one or more embodiments, a display device includes a substrate on which a pixel electrode is provided, a light emitting element on the pixel electrode and a plurality of connection electrodes between the pixel electrode and the light emitting element, the plurality of connection electrodes being arranged spaced from each other.

In one or more embodiments, each of the plurality of connection electrodes contacts the light emitting element at different points.

In one or more embodiments, the light emitting element includes a protective layer having a plurality of through-holes, on at least one side of the light emitting element, wherein the plurality of connection electrodes contacts the light emitting element through the plurality of through-holes.

In one or more embodiments, a width of a through-hole from among the plurality of through-holes is less than or equal to a width of a connection electrode from among the plurality of connection electrodes.

In one or more embodiments, the plurality of connection electrodes is spaced from an edge of the light emitting element.

In one or more embodiments, the plurality of connection electrodes has a circular or polygonal cross-section.

In one or more embodiments, the plurality of connection electrodes includes a first connection electrode, a second connection electrode, a third connection electrode, and a fourth connection electrode, wherein the first connection electrode, the second connection electrode, the third connection electrode, and the fourth connection electrode are arranged to be radially symmetrical to each other.

In one or more embodiments, the plurality of connection electrodes further includes a fifth connection electrode, wherein the first connection electrode, the second connection electrode, the third connection electrode, and the fourth connection electrode are arranged along a periphery centered on the fifth connection electrode.

In one or more embodiments, wherein each of the plurality of connection electrodes includes a reflective portion in contact with the light emitting element, and a connection portion on one surface of the reflective portion, wherein the reflective portion includes a metal having a reflectivity that is higher than a reflectivity of the connection portion.

In one or more embodiments, the light emitting element includes a current spreading layer, a first semiconductor layer, an active layer, and a second semiconductor layer, wherein the current spreading layer, the first semiconductor layer, the active layer, and the second semiconductor layer are sequentially stacked, and the current spreading layer is closer to a connection electrode from among the plurality of connection electrodes than the first semiconductor layer is.

In one or more embodiments, the display device further includes a common electrode on the light emitting element.

According to one or more embodiments, a display device includes a substrate on which a pixel electrode is provided; a light emitting element on the pixel electrode and a connection electrode between the pixel electrode and the light emitting element, the connection electrode having a body portion at a center and a plurality of branch portions extending outward from the body portion.

In one or more embodiments, wherein the body portion and the plurality of branch portions are integrated.

In one or more embodiments, the light emitting element includes a protective layer having a through-hole, on at least one side of the light emitting element, wherein the connection electrode contacts the light emitting element through the through-hole.

In one or more embodiments, a width of the through-hole is less than or equal to a width of the connection electrode.

In one or more embodiments, wherein the plurality of branch portions is spaced from an edge of the light emitting element.

In one or more embodiments, wherein the plurality of branch portions includes a first branch portion, a second branch portion, a third branch portion, and a fourth branch portion, and the plurality of branch portions extends in four directions.

In one or more embodiments, wherein the connection electrodes include a reflective portion in contact with the light emitting element, and a connection portion on one surface of the reflective portion, wherein the reflective portion includes a metal having a reflectivity that is higher than a reflectivity of the connection portion.

In one or more embodiments, the light emitting element includes a current spreading layer, a first semiconductor layer, an active layer, and a second semiconductor layer, wherein the current spreading layer, the first semiconductor layer, the active layer, and the second semiconductor layer are sequentially stacked, and the current spreading layer is closer to the connection electrode than the first semiconductor layer.

In one or more embodiments, the display device further includes a common electrode on the light emitting element.

Aspects and features of embodiments of the present disclosure are to provide a display device with improved color purity and brightness. The display device according to one or more embodiments forms a plurality of connection electrodes on the bottom surface of the light emitting element, so that the light emitting element may be stably connected to the pixel electrode without falling over during the bonding process. Accordingly, the bonding yield of the light emitting element may be improved, and color purity and brightness may be improved.

Furthermore, by distributing a plurality of connection electrodes on one surface of the light emitting element, the current spread may be improved by dispersing the contact between the connection electrode and the light emitting element.

However, the effects of the present disclosure are not limited to the aforementioned effects, and various other effects are included in the present disclosure.

### BRIEF DESCRIPTION OF THE DRAWINGS

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is an equivalent circuit diagram illustrating a sub-pixel according to one or more embodiments.

FIG. 5 is an equivalent circuit diagram illustrating a sub-pixel according to one or more embodiments.

FIG. 6 is a layout diagram illustrating a plurality of pixels in a display area according to one or more embodiments.

FIG. 7 is a cross-sectional view illustrating a display device taken along the line I1-I1′ of FIG. 6.

FIG. 8 is a perspective view of a light emitting element according to one or more embodiments.

FIG. 9 is an enlarged view of an area A of FIG. 7 and a cross-sectional view of the display device taken along the line II-II′ of FIG. 8.

FIG. 10 is an enlarged view of the area A of FIG. 7 according to one or more embodiments.

FIG. 11 is a plan view of a light emitting element and a connecting electrode according to one or more embodiments.

FIG. 12 is a perspective view of the light emitting element and connection electrode of FIG. 11.

FIG. 13 is a plan view of a light emitting element and connection electrode according to one or more embodiments.

FIG. 14 is a perspective view of a light emitting element and a connection electrode of FIG. 13.

FIG. 15 is a perspective view of a light emitting element and a connection electrode to illustrate a defect that occurs when a single connection electrode is disposed on the light emitting element.

FIG. 16 is a perspective view illustrating a bonding defect of a light emitting element bonded by one connection electrode.

FIGS. 17-29 are diagrams to illustrate a method of manufacturing a display device according to one or more embodiments.

FIG. 30 is an example diagram schematically showing a virtual reality device including a display device according to one or more embodiments.

FIG. 31 is an example diagram schematically showing a smart device including a display device according to one or more embodiments.

FIG. 32 is a diagram of an example schematically showing a vehicle including a display device according to one or more embodiments.

FIG. 33 is a diagram of an example schematically showing a transparent display device including a display device according to one or more embodiments.

### DETAILED DESCRIPTION

Embodiments of the present disclosure will now be described more fully hereinafter with reference to the accompanying drawings. Embodiments may, however, be provided in different forms and should not be construed as limiting. The same reference numbers indicate the same components throughout the present disclosure. In the accompanying figures, the thickness of layers and regions may be exaggerated for clarity.

Some of the parts which are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “spaced from,” “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the present disclosure and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, specific embodiments will be described with reference to the accompanying drawings.

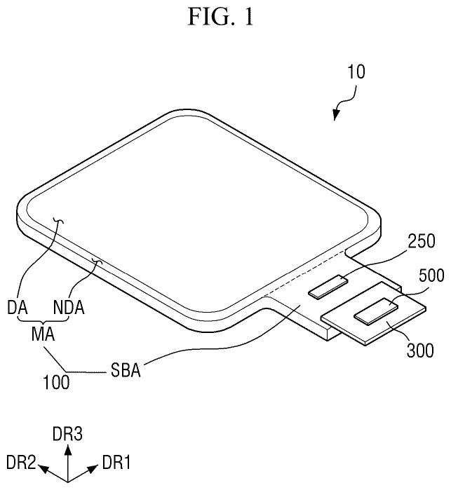

FIG. 1 is a perspective view illustrating a display device according to one or more embodiments.

Referring to FIG. 1, a display device 10 is a device for displaying video or still images, such as mobile phones, smart phones, tablet personal computers, and portable electronic devices such as smart watches, watch phones, mobile communication terminals, electronic notebooks, e-books, portable multimedia players (PMP), navigation, and ultra mobile PCs (UMPC), as well as display screens for a variety of products such as televisions, laptops, monitors, billboards, and/or the internet of things (IOT) device.

The display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, a micro light emitting diode is referred to as a light emitting diode in the following for convenience of explanation.

The display device 10 includes a display panel 100, a display driving circuit 250, a circuit board 300, and a power supply circuit 500.

The display panel 100 may be formed as a rectangular-shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a predetermined curvature) or may be formed at a right angle. The planar shape of the display panel 100 is not limited to a rectangle, and may be formed in other polygonal, circular, or oval shapes. The display panel 100 may be formed flat but is not limited thereto. For example, the display panel 100 may include curved portions with a constant curvature or a changing curvature formed at left and right ends of the display panel 100. Additionally, the display panel 100 may be formed to be flexible, such as to be able to be bent, curved, folded, and/or rolled.

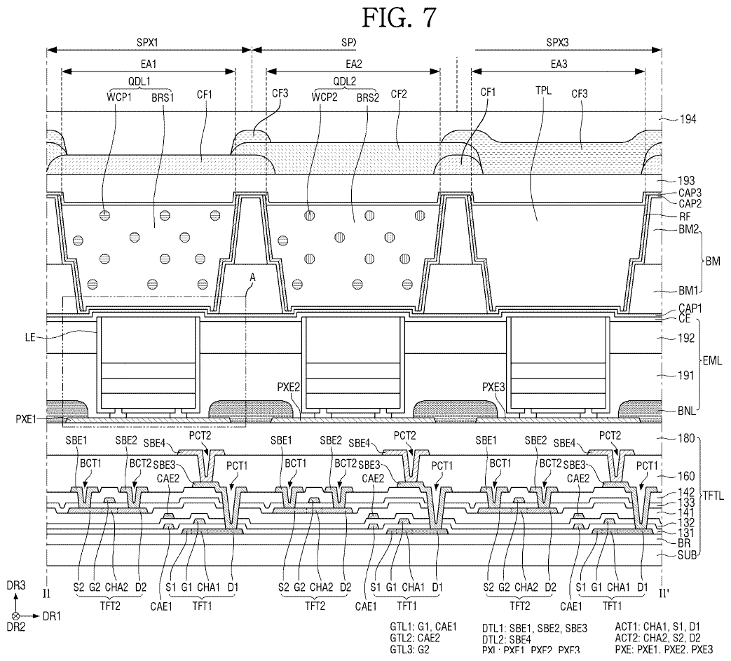

The display panel 100 (e.g., a substrate SUB of FIG. 7) may include a main area MA and a sub-area SBA.

The main area MA may include a display area DA that displays an image and a non-display area NDA that is a peripheral area of the display area DA and is around (e.g., surrounding) the display area DA along an edge or a periphery of the display area DA. The display area DA may include a plurality of pixels that display an image. For example, the pixel may include a first sub-pixel that emits first light, a second sub-pixel that emits second light, and a third sub-pixel that emits third light.

The sub-area SBA may protrude from one side of the main area MA in the second direction DR2. Although FIG. 1 illustrates the sub-area SBA being unfolded, the sub-area SBA may be bent, and in this case, may be disposed on the bottom surface of the display panel 100. When the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, or an ultrasonic bonding method but is not limited thereto. For example, the display driving circuit 250 may be attached to the circuit board 300 using a chip-on-film (COF) method.

The circuit board 300 may be attached to one end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible film, such as a flexible printed circuit board (FPCB), a printed circuit board (PCB), or a chip-on-film (COF).

The power supply circuit 500 (e.g., power supply unit) may generate and/or supply a plurality of panel-driving voltages according to an external power supply voltage. The power supply circuit 500 may be formed as an integrated circuit (IC) and attached to the circuit board 300 using a COF method.

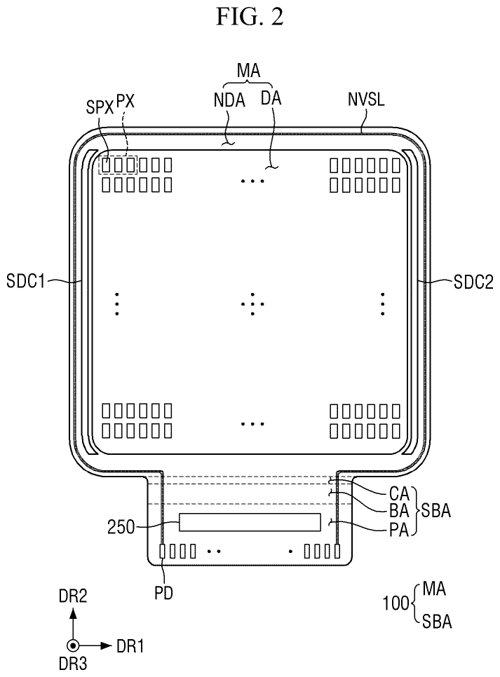

FIG. 2 is a layout diagram illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be placed adjacent to the display area DA. The non-display area NDA may be an area outside the display area DA. The non-display area NDA may be arranged to be around (e.g., to surround) the display area DA. The non-display area NDA may be an edge area of the display panel 100.

A first scan driving unit (or a first scan driving portion) SDC1 and a second scan driving unit (or a second scan driving portion) SDC2 may be disposed in the non-display area NDA. The first scan driving unit SDC1 is disposed on one side (for example, the left side) of the display panel 100, and the second scan driving unit SDC2 is disposed on the other side (for example, the right side) of the display panel 100. However, it is not limited thereto. Each of the first scan driving unit SDC1 and the second scan driving unit SDC2 may be electrically connected to the display driving circuit 250 through scan fan-out lines. Each of the first scan driving unit SDC1 and the second scan driving unit SDC2 may receive a scan control signal from the display driving circuit 250, generate scan signals according to the scan control signal, and output them to the scan lines.

The sub-area SBA may protrude from one side of the main area MA in the second direction DR2. The length of the sub-area SBA in the second direction DR2 may be smaller than the length of the main area MA in the second direction DR2. The length in the first direction DR1 of the sub-area SBA is smaller than the length in the first direction DR1 of the main area MA or may be substantially equal to the length in the first direction DR1 of the main area MA. The sub-area SBA may be curved and may be disposed at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be disposed below the connection area CA and below the main area MA (e.g., in a thickness direction (e.g., the third direction DR3)). The bending area BA may be disposed between the connection area CA and the pad area PA. One side of the bending area BA may be in contact with the connection area CA, and the other side of the bending area BA may be in contact with the pad area PA.

A non-display power supply line NVSL may be disposed in the non-display area NDA, the connection area CA, the bending area BA, and the pad area PA.

The non-display power supply line NVSL may be disposed on four sides of the display area DA in the non-display area NDA. The non-display power supply line NVSL may be arranged to be around (e.g., to surround) at least three sides of the display area DA. For example, the non-display power supply line NVSL may be around (e.g., may surround) the left, top, and right sides of the display area DA and may be disposed on at least a portion of the lower side. Further, the non-display power supply line NVSL may be disposed outside the first scan driving unit SDC1 and outside the second scan driving unit SDC2. For example, the non-display power supply line NVSL may be disposed on the left side of the first scan driving unit SDC1 and on the right side of the second scan driving unit SDC2. The non-display power supply line NVSL may be disposed between the first scan driving unit SDC1 and the edge of the substrate SUB (see, for example, FIG. 7) and between the second scan driving unit SDC2 and the edge of the substrate SUB. Alternatively, the non-display power supply line NVSL may overlap the first scan driving unit SDC1 and the second scan driving unit SDC2.

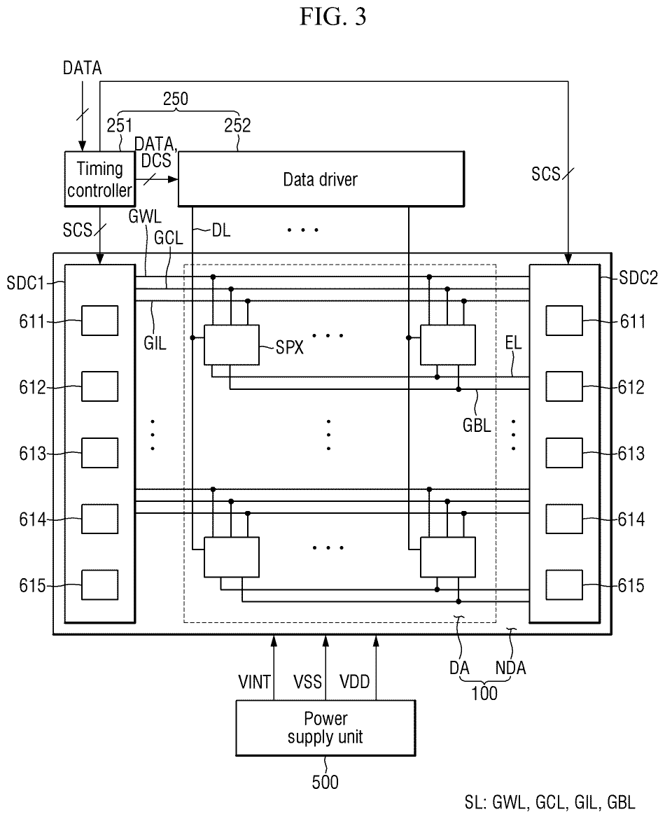

The non-display power supply line NVSL may be disposed at the left and right edges of the connection area CA and the bending area BA. The non-display power supply line NVSL may be connected to a pad PD adjacent to one side edge and a pad PD adjacent to the other side edge from among the pads PD in the pad area PA. The non-display power supply line NVSL may be supplied with a second driving voltage (VSS of FIG. 3) from a power supply circuit (500 of FIG. 1) disposed on the circuit board (300 of FIG. 1).

FIG. 3 is a block diagram illustrating a display device according to one or more embodiments.

Referring to FIG. 3, the display area DA includes a plurality of pixels PX, a plurality of scan lines SL, a plurality of emission control lines EL, and a plurality of data lines DL. According to one or more embodiments, each of the plurality of pixels PX includes a plurality of sub-pixels SPX.

The plurality of pixels PX may be arranged in a matrix form in the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1 and may be arranged along the second direction DR2. The plurality of data lines DL may extend in the second direction DR2 and may be arranged along the first direction DR1. The plurality of scan lines SL may include a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light through the light emitting elements according to the data voltage.

The non-display area NDA includes a first scan driving unit SDC1, a second scan driving unit SDC2, and a display driving circuit 250.

Each of the first scan driving unit SDC1 and the second scan driving unit SDC2 may include a write scan signal output unit 611, a control scan signal output unit 612, an initialization scan signal output unit 613, a bias scan signal output unit 614, and a light emitting signal output unit 615. Each of the write scan signal output unit 611, the control scan signal output unit 612, the initialization scan signal output unit 613, the bias scan signal output unit 614, and the light emitting signal output unit 615 may receive a scan timing control signal SCS from the timing control circuit 251. The write scan signal output unit 611 may generate write scan signals according to the scan timing control signal SCS of the timing control circuit 251 and sequentially output them to the write scan lines GWL. The control scan signal output unit 612 may generate control scan signals according to the scan timing control signal SCS and sequentially output them to the control scan lines GCL. The initialization scan signal output unit 613 may generate initialization scan signals according to the scan timing control signal SCS and sequentially output them to the initialization scan lines GIL. The bias scan signal output unit 614 may generate bias scan signals according to the scan timing control signal SCS and sequentially output them to the bias scan lines GBL. The light emitting signal output unit 615 may generate light emitting control signals according to the scan timing control signal SCS and sequentially output them to the emission control lines EL.

The display driving circuit 250 includes a timing control circuit 251 and a data driving circuit 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing control circuit 251 may receive digital video data DATA and timing signals from an external source. The timing control circuit 251 may generate the scan timing control signal SCS and the data timing control signal DCS to control the display panel 100 according to timing signals. The timing control circuit 251 may output the scan timing control signal SCS to the first scan driving unit SDC1 and the second scan driving unit SDC2. The timing control circuit 251 may output digital video data DATA and a data timing control signal DCS to the data driving circuit 252.

The data driving circuit 252 may receive digital video data DATA and a data timing control signal DCS from the timing control circuit 251.

The data driving circuit 252 may supply respective data signals (e.g., analog data voltages) to the sub-pixels SPX. For example, the data driving circuit 252 may convert the digital video data DATA into analog data voltages according to the data timing control signal DCS and output them to the data lines DL. Sub-pixels SPX may be selected by the write scan signals of the first scan driving unit SDC1 and the second scan driving unit SDC2, and data signals may be supplied to the selected sub-pixels SPX.

The power supply circuit 500 may generate a plurality of panel driving voltages according to an external power supply voltage. For example, the power supply circuit 500 may generate and may supply a first driving voltage VDD, a second driving voltage VSS, and a third driving voltage VINT to the display panel 100.

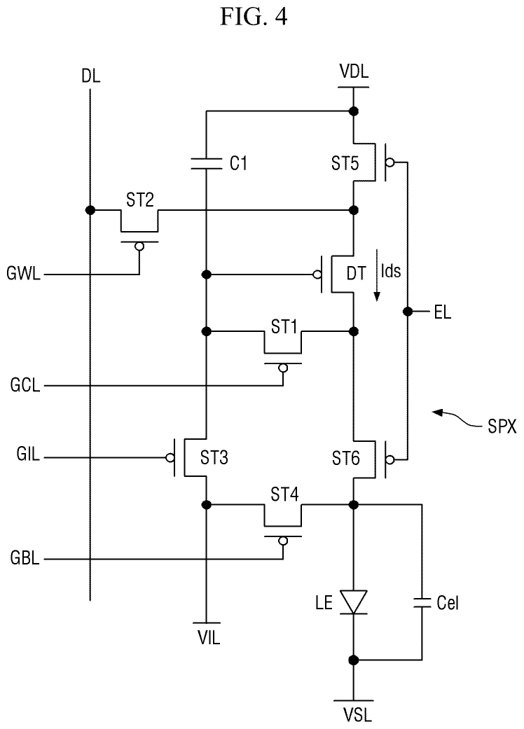

FIG. 4 is an equivalent circuit diagram illustrating a sub-pixel according to one or more embodiments.

Referring to FIG. 4, the sub-pixel SPX according to one or more embodiments may be connected to scan lines GWL, GIL, GCL, and GBL, an emission control line EL, and a data line DL. For example, the sub-pixel SPX1 may be connected to the write scan line GWL, the initialization scan line GIL, the control scan line GCL, the bias scan line GBL, the emission control line EL, and the data line DL.

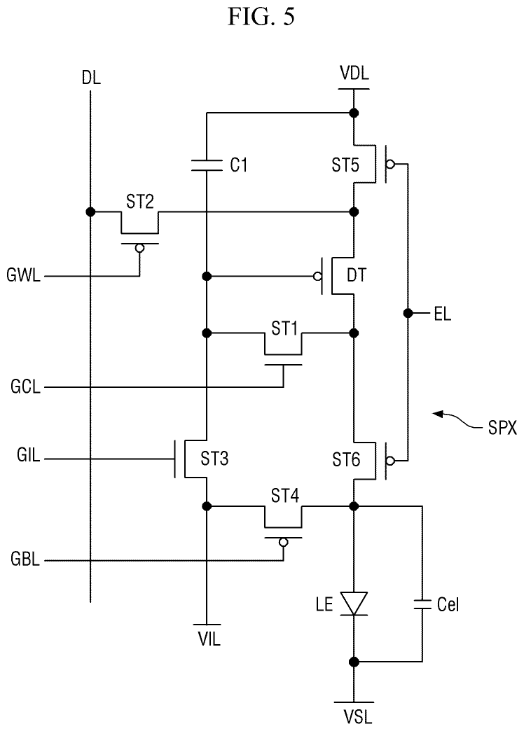

The sub-pixel SPX according to one or more embodiments includes a driving transistor DT, switch elements, a capacitor C1, and a light emitting element LE. The switch elements include first to sixth transistors ST1, ST2, ST3, ST4, ST5, and ST6. The driving transistor DT, switch elements, and capacitor C1 may be referred to as a pixel circuit. The pixel circuit may include a driving transistor DT, at least one switching transistor (e.g., ST1, ST2, ST3, ST4, ST5, and ST6), and a capacitor C1. In one or more embodiments, the pixel circuit may include first to sixth transistors ST1, ST2, ST3, ST4, ST5, and ST6 as the switching transistor. The configuration of the pixel circuit is not limited to the embodiments of FIGS. 4 and 5 and may be changed in various ways.

The driving transistor DT includes a gate electrode, a first electrode, and a second electrode. The driving transistor DT controls the drain-source current (e.g., hereinafter referred to as “driving current Ids”) flowing between the first electrode and the second electrode according to the data voltage applied to the gate electrode.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE is connected to the first electrode of the fourth transistor ST4 and the second electrode of the sixth transistor ST6, and the cathode electrode may be connected to a second power supply line VSL to which a second power supply voltage is applied. A parasitic capacitance Cel may be formed between the anode electrode and the cathode electrode of the light emitting element LE.

The capacitor C1 is formed between the gate electrode of the driving transistor DT and the first power supply line VDL to which the first power supply voltage is applied. The first power supply voltage may be at a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as P-type metal oxide semiconductor field effect transistors (P-type MOSFETs). In this case, the active layer of each of the first to sixth transistors ST1, ST2, ST3, ST4, ST5, and ST6 and the driving transistor DT may be formed of polysilicon.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. The gate electrodes of the fifth and sixth transistor ST5 and ST6 may be connected to the emission control line EL. Because the first to sixth transistors ST1, ST2, ST3, ST4, ST5, and ST6 are formed as P-type MOSFET, they may be turned on when a scan signal of the gate low voltage and an emission signal (e.g., of a low voltage) are applied to the control scan line GCL, the initialization scan line GIL, the write scan line GWL, the bias scan line GBL, and the emission control line EL, respectively. One electrode of the third transistor ST3 and one electrode of the fourth transistor ST4 may be connected to an initialization voltage line VIL.

For example, the first transistor ST1 may be connected between the second electrode and the gate electrode of the driving transistor DT. The second transistor ST2 may be connected between the data line DL and the first electrode of the driving transistor DT. The third transistor ST3 may be connected between the initialization voltage line VIL and the gate electrode of the driving transistor DT. The fourth transistor ST4 may be connected between the initialization voltage line VIL and the light-emitting element LE. The fifth transistor ST5 may be connected between the first power supply line VDL and the first electrode of the driving transistor DT. The sixth transistor ST6 may be connected between the second electrode of the driving transistor DT and the light-emitting element LE.

FIG. 5 is an equivalent circuit diagram illustrating a sub-pixel according to one or more embodiments.

Referring to FIG. 5, the driving transistor DT, the second transistor ST2, the fourth transistor ST4, the fifth transistor ST5, and the sixth transistor ST6 are formed of P-type MOSFET, and the first transistor ST1 and the third transistor ST3 may be formed as N-type MOSFET. The active layer of each of the driving transistor DT, the second transistor ST2, the fourth transistor ST4, the fifth transistor ST5, and the sixth transistor ST6 formed as the P-type MOSFET may be formed of polysilicon, and the active layer of each of the first transistor ST1 and the third transistor ST3 formed as the N-type MOSFET may be formed of the oxide semiconductor. In this case, transistors formed of polysilicon and transistors formed of oxide semiconductors may be arranged in different layers.

Because the first transistor ST1 and the third transistor ST3 are formed as N-type MOSFET, the first transistor ST1 may be turned on when a control scan signal with a gate high voltage is applied to the control scan line GCL, and the third transistor ST3 may be turned on when an initialization scan signal is applied to the initialization scan line GIL. In comparison, the second transistor ST2, the fourth transistor ST4, the fifth transistor ST5, and the sixth transistor ST6 are formed as P-type MOSFET, so they may be turned on when a scan signal with a gate low voltage and an emission signal (e.g., with a low voltage) are applied to the write scan line GWL, the bias scan line GBL, and the emission control line EL, respectively.

Alternatively, the fourth transistor ST4 in FIG. 4 may be formed of the N-type MOSFET. In this case, the active layer of each fourth transistor ST4 may be formed of the oxide semiconductor. When the fourth transistor ST4 is formed of N-type MOSFET, it may be turned on when a bias scan signal of a gate high voltage is applied to the bias scan line GBL.

In one or more embodiments, the first to sixth transistors ST1, ST2, ST3, ST4, ST5, and ST6 and the driving transistor DT may all be formed as N-type MOSFET. In this case, the active layer of each of the first to sixth transistors ST1, ST2, ST3, ST4, ST5, and ST6 and the driving transistor DT may be formed of an oxide semiconductor.

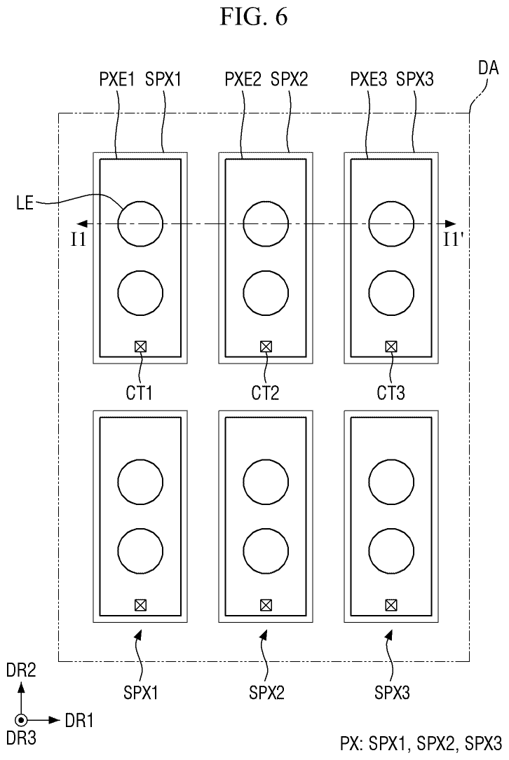

FIG. 6 is a layout diagram illustrating a plurality of pixels in a display area according to one or more embodiments.

Referring to FIG. 6, each of the plurality of pixels PX in the display area DA may include a first sub-pixel SPX1, a second sub-pixel SPX2, and a third sub-pixel SPX3.

A plurality of pixels PX may be arranged in a matrix form. In each of the plurality of pixels PX, the first sub-pixel SPX1, the second sub-pixel SPX2, and the third sub-pixel SPX3 may be arranged along the first direction DR1.

The first sub-pixel SPX1 may emit light of the first color, the second sub-pixel SPX2 may emit light of the second color, and the third sub-pixel SPX3 may emit light of the third color. Here, the first color light may be light in a red wavelength band, the second color light may be light in a green wavelength band, and the third color light may be light in a blue wavelength band. For example, the blue wavelength band may indicate that the main peak wavelength of the light is contained in the wavelength band of approximately 370 nm to 460 nm, and the green wavelength band may indicate that the main peak wavelength of light is contained in the wavelength band of approximately 480 nm to 560 nm, and the red wavelength band may indicate that the main peak wavelength of light is contained in the wavelength band of approximately 600 nm to 750 nm.

Each of the first to third sub-pixels SPX1 to SPX3 may include a pixel electrode PXE and one or more light emitting elements LE.

Each of the first pixel electrode PXE1, the second pixel electrode PXE2, and the third pixel electrode PXE3 has a rectangular planar shape with a short side in the first direction DR1 and a long side in the second direction DR2. However, the present disclosure is not limited thereto.

A plurality of light emitting elements LE may be arranged to overlap the pixel electrodes PXE1, PXE2, and PXE3.

The first pixel electrode PXE1 may be electrically connected to the first electrode of the fourth transistor (ST4 in FIGS. 4 and 5) and the second electrode of the sixth transistor (ST6 in FIGS. 4 and 5) of the first sub-pixel SPX1 through a first connection hole CT1. The second pixel electrode PXE2 may be electrically connected to the first electrode of the fourth transistor (ST4 in FIGS. 4 and 5) and the second electrode of the sixth transistor (ST6 in FIGS. 4 and 5) of the second sub-pixel SPX2 through a second connection hole CT2. The third pixel electrode PXE3 may be electrically connected to the first electrode of the fourth transistor (ST4 in FIGS. 4 and 5) and the second electrode of the sixth transistor (ST6 in FIGS. 4 and 5) of the third sub-pixel SPX3 through a third connection hole CT3.

A plurality of light emitting elements LE may be disposed on each of the first pixel electrode PXE1, the second pixel electrode PXE2, and the third pixel electrode PXE3. The same number of lights emitting elements LE may be disposed on each of the first pixel electrode PXE1, the second pixel electrode PXE2, and the third pixel electrode PXE3. For example, two light emitting elements LE may be disposed on each of the first pixel electrode PXE1, the second pixel electrode PXE2, and the third pixel electrode PXE3. The plurality of light emitting elements LE may emit third light, that is, light in the blue wavelength band, but is not limited thereto.

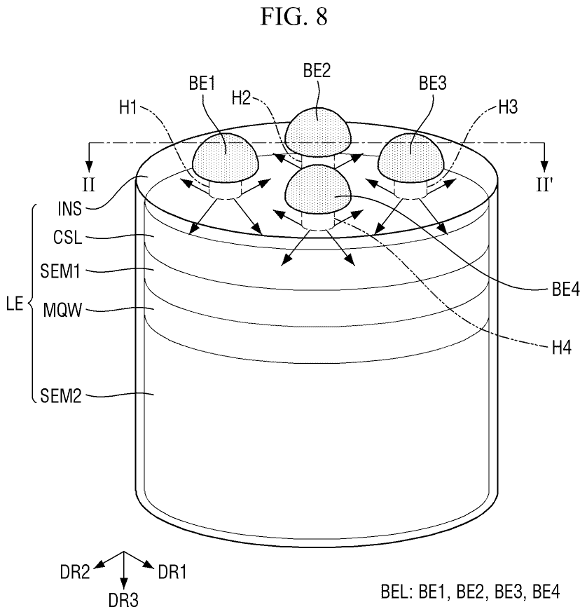

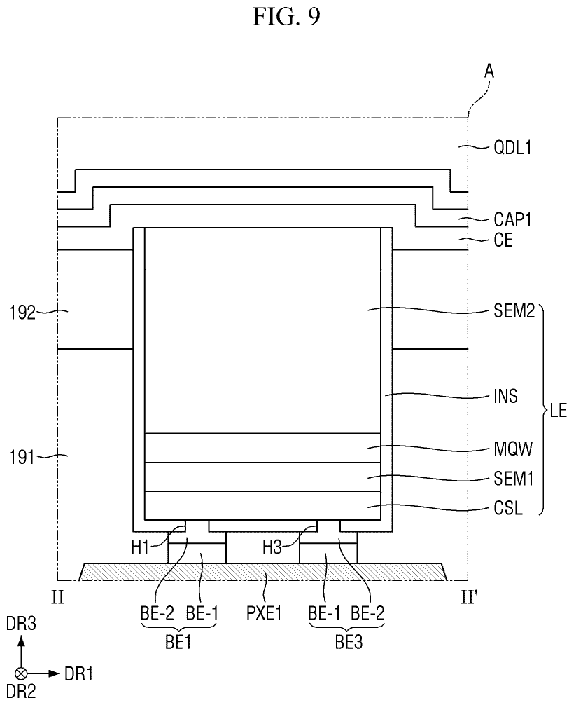

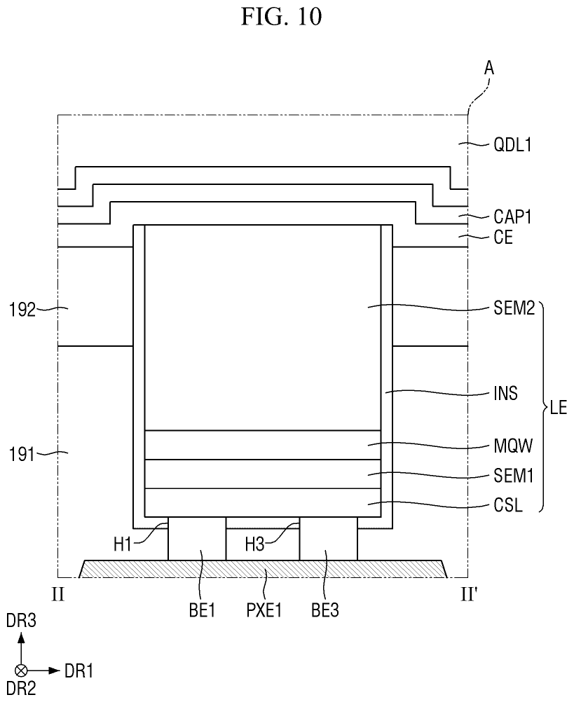

FIG. 7 is a cross-sectional view of a display device taken along the line I1-I1′ of FIG. 6. FIG. 8 is a perspective view of a light emitting element according to one or more embodiments. FIG. 9 is an enlarged view of an area A of FIG. 7 and a cross-sectional view of the display device taken along the line II-II′ of FIG. 8. FIG. 10 is an enlarged view of the area A of FIG. 7 according to one or more embodiments.

Referring to FIGS. 7 and 8, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be disposed on the substrate SUB. The barrier film BR is a membrane for protecting the transistors of a thin film transistor layer TFTL and the light emitting element LE of a light emitting element layer EML from moisture penetrating through the substrate SUB, which is vulnerable to moisture penetration. The barrier film BR may be composed of a plurality of inorganic films stacked alternately. For example, the barrier film BR may be formed as a multilayer of alternating inorganic films of one or more of a silicon nitride layer, a silicon oxynitride layer, a silicon oxide layer, a titanium oxide layer, and/or an aluminium oxide layer.

A first thin film transistor TFT1 may be disposed on the barrier film BR. The first thin film transistor TFT1 may be either the fourth transistor ST4 or the sixth transistor ST6 shown in FIG. 5. The first thin film transistor TFT1 may include a first active layer ACT1 and a first gate electrode G1.

The first active layer ACT1 of the first thin film transistor TFT1 may be disposed on the barrier film BR. The first active layer ACT1 of the first thin film transistor TFT1 may include polycrystalline silicon, single crystalline silicon, low-temperature polycrystalline silicon, and/or amorphous silicon.

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be areas in which the silicon semiconductor is doped with ions to make it conductive.

A first gate insulating film 131 may be disposed on the first channel area CHA1, the first source area S1, and the first drain area D1 of the first thin film transistor TFT1 and the barrier film BR. The first gate insulating film 131 may be formed of an inorganic film, for example, a silicon nitride layer, a silicon oxynitride layer, a silicon oxide layer, a titanium oxide layer, and/or an aluminium oxide layer.

A first gate metal layer GTL1 may be disposed on the first gate insulating film 131. The first gate metal layer GTL1 may include the first gate electrode G1 of the first thin film transistor TFT1 and a first capacitor electrode CAE1. The first gate electrode G1 may overlap the first active layer ACT1 in the third direction DR3. In FIG. 7, the first gate electrode G1 and the first capacitor electrode CAE1 are shown to be spaced (e.g., disposed apart) from each other, but the first gate electrode G1 and the first capacitor electrode CAE1 may be connected to each other. The first gate metal layer GTL1 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof.

A second gate insulating film 132 may be disposed on the first gate electrode G1 of the first thin film transistor TFT1, the first capacitor electrode CAE1, and the first gate insulating film 131. The second gate insulating film 132 may be formed of an inorganic film, for example, a silicon nitride layer, a silicon oxynitride layer, a silicon oxide layer, a titanium oxide layer, and/or an aluminium oxide layer.

A second gate metal layer GTL2 may be disposed on the second gate insulating film 132. The second gate metal layer GTL2 may include a second capacitor electrode CAE2. The second capacitor electrode CAE2 may overlap the first capacitor electrode CAE1 in the third direction DR3. Because the second gate insulating film 132 has a suitable permittivity (e.g., a predetermined permittivity), a capacitor (C1 in FIG. 5) may be formed by the first capacitor electrode CAE1, the second capacitor electrode CAE2, and the second gate insulating film 132 disposed between them. The second gate metal layer GTL2 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof.

A first interlayer insulating film 141 may be disposed on the second capacitor electrode CAE2 and the second gate insulating film 132. The first interlayer insulating film 141 may be formed of an inorganic film, such as a silicon nitride layer, a silicon 1 oxynitride layer, a silicon oxide layer, a titanium oxide layer, or an aluminium oxide layer.

A second thin film transistor TFT2 may be disposed on the first interlayer insulating film 141. The second thin film transistor TFT2 may be either the first transistor ST1 or the third transistor ST3 shown in FIG. 5. The second thin film transistor TFT2 may include a second active layer ACT2 and a second gate electrode G2.

The second active layer ACT2 of the second thin film transistor TFT2 may be disposed on the first interlayer insulating film 141. The second active layer ACT2 may include an oxide semiconductor. For example, the second active layer ACT2 may include IGZO (indium (In), gallium (Ga), zinc (Zn) and oxygen (O)), IGZTO (indium (In), gallium (Ga), zinc (Zn), tin (Sn) and/or oxygen (O)), and/or IGTO (indium (In), gallium (Ga), tin (Sn) and oxygen (O)).

The second active layer ACT2 may include a second channel area CHA2, a second source area S2, and a second drain area D2. The second channel area CHA2 may be an area that overlaps the second gate electrode G2 in the third direction DR3. The second source area S2 may be disposed on one side of the second channel area CHA2, and the second drain area D2 may be disposed on the other side of the second channel area CHA2. The second source area S2 and the second drain area D2 may be areas that do not overlap the second gate electrode G2 in the third direction DR3. The second source area S2 and the second drain area D2 may be areas in which the oxide semiconductor is reduced to make it conductive.

A third gate insulating film 133 may be disposed on the second active layer ACT2 of the second thin film transistor TFT2 and the first interlayer insulating film 141. The third gate insulating film 133 may be formed of an inorganic film, for example, a silicon nitride layer, a silicon oxynitride layer, a silicon oxide layer, a titanium oxide layer, and/or an aluminium oxide layer.

A third gate metal layer GTL3 may be disposed on the third gate insulating film 133. The third gate metal layer GTL3 may include the second gate electrode G2 of the second thin film transistor TFT2. The second gate electrode G2 may overlap the second active layer ACT2 in the third direction DR3. The third gate metal layer GTL3 may be formed as a single layer or multiple layers of molybdenum (Mo), aluminium (AI), chromium (Cr), gold (Au), titanium (Ti), nickel (Ni), neodymium (Nd), and/or copper (Cu), and/or an alloy thereof.

A second interlayer insulating film 142 may be disposed on the second gate electrode G2 of the second thin film transistor TFT2 and the third gate insulating film 133. The second interlayer insulating film 142 may be formed of an inorganic film, for example, a silicon nitride layer, a silicon oxynitride layer, a silicon oxide layer, a titanium oxide layer, and/or an aluminium oxide layer.

A first data metal layer DTL1 may be disposed on the second interlayer insulating film 142. The first data metal layer DTL1 may include a first source connection electrode SBE3, a second source connection electrode SBE1, and a third source connection electrode SBE2. The first source connection electrode SBE3 may be connected to the first drain area D1 of the first active layer ACT1 through a first source contact hole PCT1 penetrating a first gate insulating film 131, a second gate insulating film 132, a first interlayer insulating film 141, a third gate insulating film 133, and a second interlayer insulating film 142. A second source connection electrode SBE1 may be connected to the second source area S2 of the second active layer ACT2 through the second source connection contact hole BCT1 penetrating the second interlayer insulating film 142 and the third gate insulating film 133. The third source connection electrode SBE2 may be connected to the second drain area D2 of the second active layer ACT2 through the third source connection contact hole BCT2 penetrating the second interlayer insulating film 142 and the third gate insulating film 133. The first data metal layer DTL1 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof. For example, the first data metal layer DTL1 may include a first layer made of titanium (Ti), a second layer made of aluminum (Al), and a third layer made of titanium (Ti).

A first organic layer 160 may be disposed to flatten the step due to the first thin film transistor TFT1 and the second thin film transistor TFT2 on the first source connection electrode SBE3, the second source connection electrode SBE1, and the third source connection electrode SBE2, and on the second interlayer insulating film 142. The first organic layer 160 may be formed from an organic film such as acrylic resin, epoxy resin, phenolic resin, polyamide resin, polyimide resin, and/or the like.

A second data metal layer DTL2 may be disposed on the first organic layer 160. The second data metal layer DTL2 may include a fourth source connection electrode SBE4. The fourth source connection electrode SBE4 may be connected to the first source connection electrode SBE3 through a second pixel contact hole PCT2 penetrating the first organic layer 160. The second data metal layer DTL2 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof. For example, the second data metal layer DTL2 may include a first layer made of titanium (Ti), a second layer made of aluminum (Al), and a third layer made of titanium (Ti).

A second organic layer 180 may be disposed on the fourth source connection electrode SBE4 and the first organic layer 160. The second organic layer 180 may be formed of an organic film such as acrylic resin, epoxy resin, phenolic resin, polyamide resin, polyimide resin, and/or the like.

A light emitting element layer EML may be disposed on the second organic layer 180. The light emitting element layer EML may include pixel electrodes PXE1, PXE2, and PXE3, light emitting elements LE, a common electrode CE, and a connection electrode BE.

A pixel electrode layer PXL may be disposed on the second organic layer 180. The pixel electrode layer PXL may include a first pixel electrode PXE1, a second pixel electrode PXE2, and a third pixel electrode PXE3. In the first sub-pixel SPX1, the first pixel electrode PXE1 may be connected to the fourth source connection electrode SBE4 through a first connection hole (CT1 in FIG. 6) penetrating the second organic layer 180. In the second sub-pixel SPX2, the second pixel electrode PXE2 may be connected to the fourth source connection electrode SBE4 through a second connection hole (CT2 in FIG. 6) penetrating the second organic layer 180. In the third sub-pixel SPX3, the third pixel electrode PXE3 may be connected to the fourth source connection electrode SBE4 through a third connection hole (CT3 in FIG. 6) penetrating the second organic layer 180.

In the first sub-pixel SPX1, the first pixel electrode PXE1 may be connected to the first source area S1 or the first drain area D1 of the first thin film transistor TFT1 through the first source connection electrode SBE3 and the fourth source connection electrode SBE4. Therefore, a voltage controlled by the first thin film transistor TFT1 in the first sub-pixel SPX1 may be applied to the first pixel electrode PXE1.

In addition, in the second sub-pixel SPX2, the second pixel electrode PXE2 may be connected to the first source area S1 or the first drain area D1 of the first thin film transistor TFT1 through the first source connection electrode SBE3 and the fourth source connection electrode SBE4. Therefore, a voltage controlled by the first thin film transistor TFT1 in the second sub-pixel SPX2 may be applied to the second pixel electrode PXE2.

Further, in the third sub-pixel SPX3, the third pixel electrode PXE3 may be connected to the first source area S1 or the first drain area D1 of the first thin film transistor TFT1 through the first source connection electrode SBE3 and the fourth source connection electrode SBE4. Therefore, a voltage controlled by the first thin film transistor TFT1 in the third sub-pixel SPX3 may be applied to the third pixel electrode PXE3.

The pixel electrode layer PXL may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof. For example, the pixel electrode layer PXL may be made of copper (Cu) with low surface resistance to lower the resistance of each of the first pixel electrode PXE1, the second pixel electrode PXE2, and the third pixel electrode PXE3.

The bank layer BNL may be disposed to cover the edges of the first pixel electrode PXE1, the second pixel electrode PXE2, and the third pixel electrode PXE3. The bank layer BNL may be formed of an organic layer such as an acrylic resin, an epoxy resin, a phenolic resin, a polyamide resin, a polyimide resin, and/or the like. The bank layer BNL may include a light blocking material to prevent light from the light emitting element LE of one sub-pixel from proceeding to the neighboring sub-pixel. For example, the bank layer BNL may include an inorganic black pigment such as carbon black or an organic black pigment.

The light emitting element LE may be disposed on the first pixel electrode PXE1, the second pixel electrode PXE2, and the third pixel electrode PXE3 that are exposed and not covered by the bank layer BNL. One or more light emitting elements LE may be disposed on each of the first pixel electrode PXE1, the second pixel electrode PXE2, and the third pixel electrode PXE3.

As shown in FIG. 7, the light emitting elements LE may be disposed in each of the first light emitting area EA1, the second light emitting area EA2, and the third light emitting area EA3. The light emitting element LE may be a vertical light emitting diode element extending in the third direction DR3. That is, the length of the light emitting element LE in the third direction DR3 may be greater than the length in the horizontal direction. The length in the horizontal direction indicates the length in the first direction DR1 and/or the length in the second direction DR2. For example, the length of the light emitting element LE in the third direction DR3 may be approximately 1 μm to 5 μm. However, the present disclosure is not limited to this, and the length of the light emitting element LE in the third direction DR3 may be equal to or smaller than the length in the horizontal direction.

The light emitting element LE may be a micro light emitting diode element. Referring to FIGS. 8 and 9, a connection electrode layer BEL may be disposed between the light emitting element LE and the pixel electrode layer PXL, and the light emitting element LE may include a current spreading layer CSL, a first semiconductor layer SEM1, an active layer MQW, and a second semiconductor layer SEM2 stacked sequentially in the thickness direction of the substrate SUB, that is, the third direction DR3. In one or more embodiments, an electron blocking layer may be disposed between the first semiconductor layer SEM1 and the active layer MQW. Further, a superlattice layer may be disposed between the active layer MQW and the second semiconductor layer SEM2. Additionally, the current spreading layer CSL may be omitted.

In addition, the light emitting element LE may include a protective layer INS around (e.g., surrounding) at least a portion of the current spreading layer CSL, the first semiconductor layer SEM1, the active layer MQW, and the second semiconductor layer SEM2.

The light emitting element LE may have a cylindrical shape, a disk shape, and/or a rod shape where the height is longer than the width. However, it is not limited to this, and the light emitting element LE may be shaped like a rod, wire, tube, and/or the like, and/or may have a polygonal column shape such as a cube, cuboid, and/or hexagonal column, or may have a shape that extends in one direction but has a partially inclined outer surface (e.g., outer peripheral or circumferential surface).

The current spreading layer CSL is a layer to increase the light extraction efficiency and may be formed of a transparent conductive oxide (TCO) such as indium tin oxide (ITO) and/or indium zinc oxide (IZO) to transmit light.

The first semiconductor layer SEM1 may be disposed on the current spreading layer CSL. The length of the bottom surface of the first semiconductor layer SEM1 in the first direction DR1 or the length in the second direction DR2 may be less than the length of the connection electrode BE in the first direction DR1 and/or the length in the second direction DR2. The first semiconductor layer SEM1 may be made of GaN doped with a first conductivity type dopant such as Mg, Zn, Ca, Ba, and/or the like.

The active layer MQW may be disposed on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. In this case, the well layer may be formed of InGaN, and the barrier layer may be formed of GaN and/or AlGaN but is not limited thereto. Alternatively, the active layer MQW may have a structure in which semiconductor materials having a high energy band gap and semiconductor materials having a low energy band gap are alternately stacked with each other, and may include other Group Ill to V semiconductor materials according to the wavelength range of emitted light.

When the active layer MQW includes InGaN, the color of the emitted light may vary depending on the content of indium (In). For example, as the content of indium (In) increases, the wavelength band of light emitted by the active layer MQW may shift to the red wavelength band, and as the content of indium (In) decreases, the wavelength band of light emitted by the active layer MQW may shift to the blue wavelength band. For example, the content of indium (In) in the active layer MQW of the light emitting element LE that emits the third light (e.g., light in the blue wavelength band) may be approximately 10 wt % to 20 wt %.

The second semiconductor layer SEM2 may be disposed on the active layer MQW. The second semiconductor layer SEM2 may be doped with a second conductivity type dopant such as Si, Ge, Se, Sn, and/or the like. For example, the second semiconductor layer SEM2 may be N-GaN doped with N-type Si.

The electron blocking layer may be disposed between the first semiconductor layer SEM1 and the active layer MQW. The electron blocking layer may be a layer to suppress or prevent too many electrons from flowing into the active layer MQW. For example, the electron blocking layer may be AlGaN and/or P-AIGaN doped with P-type Mg. The electron blocking layer may be omitted.

The superlattice layer may be disposed between the active layer MQW and the second semiconductor layer SEM2. The superlattice layer may be a layer for relieving stress between the second semiconductor layer SEM2 and the active layer MQW. For example, the superlattice layer may be formed of InGaN and/or GaN. The superlattice layer may be omitted.

The protective layer INS may be disposed on one side and a side of the current spreading layer CSL, a side of the first semiconductor layer SEM1, a side of the active layer MQW, and a side of the second semiconductor layer SEM2. The protective layer INS may be a film to protect the outer surface (e.g., outer peripheral or circumferential surface) of the light emitting element LE.

The protective layer INS may be formed of an inorganic film, for example, a silicon nitride layer, a silicon oxy nitride layer, a silicon oxide layer, a titanium oxide layer, and/or an aluminum oxide layer.

The connection electrode layer BEL is disposed between the light emitting element LE and the pixel electrode layer PXL. The connection electrode layer BEL may include a plurality of connection electrodes BE1, BE2, BE3, and BE4. For example, the connection electrode layer BEL may include a first connection electrode BE1, a second connection electrode BE2, a third connection electrode BE3, and a fourth connection electrode BE4, but is limited thereto.

The plurality of connection electrodes BE1, BE2, BE3, and BE4 connect the pixel electrodes PXE1, PXE2, and PXE3 overlapped in the thickness direction and the light emitting element LE.

The plurality of connection electrodes BE1, BE2, BE3, and BE4 may be disposed on corresponding pixel electrodes PXE1, PXE2, and PXE3. The plurality of connection electrodes BE1, BE2, BE3, and BE4 may serve as a bonding metal for bonding the pixel electrodes PXE1, PXE2, and PXE3 to the light emitting elements LE during the manufacturing process.

The plurality of connection electrodes BE1, BE2, BE3, and BE4 may include a connection portion BE-1 and a reflective portion BE-2. The reflective portion BE-2 is disposed to be spaced (e.g., spaced apart) from the pixel electrodes PXE1, PXE2, and PXE3 than the connection portion BE-1, and the connection portion BE-1 is disposed on the pixel electrodes PXE1, PXE2, and PXE3 to bond the pixel electrodes PXE1, PXE2, PXE3 and the light emitting element LE. The reflective portion BE-2 may be disposed closer to the first semiconductor layer SEM1 than the connection portion BE-1. The reflective portion BE-2 serves to reflect light emitted from the light emitting element LE, which travels in the upper, lower, left, and right lateral directions rather than the upper direction, thereby preventing or reducing mixing of light emitted from the light emitting elements LE in the adjacent light emitting areas EA1, EA2, and EA3. The reflective portion BE-2 may include more of a metal material with a higher reflectivity, such as Al, than the connection portion BE-1. The reflective portion BE-2 may include a metal having a reflectivity that is higher than a reflectivity of the connection portion BE-1.

Each of the plurality of connection electrodes BE1, BE2, BE3, and BE4 may be in contact with the pixel electrodes PXE1, PXE2, and PXE3. Each of the plurality of connection electrodes BE1, BE2, BE3, and BE4 may be in direct contact with the current spreading layer CSL of the light emitting element LE. Each of the plurality of connection electrodes BE1, BE2, BE3, and BE4 contacts the light emitting element LE at different points. To this end, the protective layer INS may have a plurality of through-holes so that the plurality of connection electrodes BE1, BE2, BE3, and BE4 directly contact with the current spreading layer CSL. For example, the protective layer INS may include a plurality of through-holes H1, H2, H3, and H4 on one surface that contacts the plurality of connection electrodes BE1, BE2, BE3, and BE4. The current spreading layer CSL may be exposed through the plurality of through-holes H1, H2, H3, and H4.

The plurality of through holes H1, H2, H3, and H4 may have a one-to-one correspondence with the plurality of connection electrodes BE. For example, the protective layer INS may include a first through-hole H1, a second through-hole H2, a third through-hole H3, and a fourth through-hole H4. The first through-hole H1 overlaps the first connection electrode BE1 in the thickness direction (e.g., the third direction DR3), and the width of the first through-hole H1 may be smaller than the width of the first connection electrode BE1. The second through-hole H2 overlaps the second connection electrode BE2 in the thickness direction, and the width of the second through-hole H2 may be smaller than the width of the second connection electrode BE2. The third through-hole H3 overlaps the third connection electrode BE3 in the thickness direction, and the width of the third through-hole H3 may be smaller than the width of the third connection electrode BE3. The fourth through-hole H4 overlaps the fourth connection electrode BE4 in the thickness direction, and the width of the fourth through-hole H4 may be smaller than the width of the fourth connection electrode BE4. In one or more other embodiments, as shown in FIG. 10, each width of the plurality of through-holes H1, H2, H3, and H4 may be the same as the width of the corresponding connection electrodes BE1, BE2, BE3, and BE4. For example, the width of the first-through hole H1 may be equal to the width of the first connection electrode BE1. The width of the third through-hole H3 may be equal to the width of the third connection electrode BE3. Similarly, in one or more embodiments, the width of the second through-hole H2 may be equal to the width of the second connection electrode BE2, and the width of the fourth through-hole H4 may be equal to the width of the fourth connection electrode BE4.

The plurality of through holes H1, H2, H3, and H4 may be spaced (e.g., spaced apart) from each other on a plane. The distance between the plurality of neighboring through-holes H1, H2, H3, and H4 may be the same. The distance between each of the plurality of through-holes H1, H2, H3, and H4 from the center of the light emitting element LE may be the same but is not limited thereto. Each of the plurality of through-holes H1, H2, H3, and H4 may be circular in a plan view, but is not limited thereto. For example, the plurality of through-holes H1, H2, H3, and H4 may be rectangular or triangular.

The sizes of the plurality of through-holes H1, H2, H3, and H4 may be the same, but are not limited thereto. The plurality of through-holes H1, H2, H3, and H4 may be arranged to be spaced (e.g., spaced apart) from the edge of the light emitting element LE. The through-holes H1, H2, H3, and H4 may be arranged to be spaced (e.g., spaced apart) from each other by the same distance from the edge of the light emitting element LE. For example, the distance between the first through-hole H1 and the edge of the light emitting element LE may be the same as the distance between the second through-hole H2 and the edge of the light emitting element LE. The distance between the first through-hole H1 and the edge of the light emitting element LE may be the same as the distance between the third through-hole H3 and the edge of the light emitting element LE. Also, the distance between the first through-hole H1 and the edge of the light emitting element LE may be the same as the distance between the fourth through-hole H4 and the edge of the light emitting element LE.

The plurality of connection electrodes BE1, BE2, BE3, and BE4 may be in direct contact through through-holes H1, H2, H3, and H4 in the protective layer INS. The width of the through-holes H1, H2, H3, and H4 may be the same as or narrower than the width of the connection electrodes BE1, BE2, BE3, and BE4.

The first connection electrode BE1, the second connection electrode BE2, the third connection electrode BE3, and the fourth connection electrode BE4 may be spaced (e.g., spaced apart) from each other on a plane. The distance between neighboring connection electrodes BE1, BE2, BE3, and BE4 may be the same.

The size of each connection electrode BE1, BE2, BE3, and BE4 may be the same, but is not limited thereto. Each of the connection electrodes BE1, BE2, BE3, and BE4 may have any shape as long as it may support the light emitting element LE. For example, the cross-section of each connection electrode BE1, BE2, BE3, and BE4 may be not only circular but also polygonal, such as square, pentagon, and/or hexagon. However, the height of each connection electrode BE1, BE2, BE3, and BE4 is all the same, so that the light emitting element LE on top may be supported so that the light emitting element LE may stand stably on the pixel electrodes PXE1, PXE2, and PXE3 without falling over.

The plurality of connection electrodes BE1, BE2, BE3, and BE4 may reduce the resistance between the light emitting element LE and the pixel electrodes PXE1, PXE2, and PXE3 when the light emitting element LE is electrically connected to the pixel electrodes PXE1, PXE2, and PXE3 in the display panel 100 according to one or more embodiments. The connection electrode BE (BE1, BE2, BE3, and BE4) may include a conductive metal. For example, the connection electrode BE may include gold (Au), copper (Cu), tin (Sn), titanium (Ti), aluminum (Al), and/or silver (Ag). For example, the connection electrode BE may include a 9:1 alloy, 8:2 alloy, and/or 7:3 alloy of gold and tin, or may include an alloy of copper, silver, and/or tin (SAC305).

The connection electrode BE and the pixel electrodes PXE1, PXE2, and PXE3 may be bonded by a eutectic process.

A third organic layer 191 may be disposed to cover the bank layer BNL and a portion of a side surfaces of the plurality of light emitting elements LE. The third organic layer 191 may be formed of an organic layer such as an acrylic resin, an epoxy resin, a phenolic resin, a polyamide resin, a polyimide resin, and/or the like.

A fourth organic layer 192 may be disposed on the third organic layer 191. The fourth organic layer 192 may be disposed to cover a portion of a side surface of each of the plurality of light emitting elements LE. The fourth organic layer 192 may be disposed lower than the plurality of light emitting elements LE to expose a top of the light emitting elements LE.

The fourth organic layer 192 may be formed of an organic layer such as an acrylic resin, an epoxy resin, a phenolic resin, a polyamide resin, a polyimide resin, and/or the like.

The third organic layer 191 and the fourth organic layer 192 are layers for flattening steps caused by the plurality of light emitting elements LE. If the height of the third organic layer 191 is arranged such that the third organic layer 191 may cover most of the side surfaces of each of the plurality of light emitting elements LE, the fourth organic layer 192 may be omitted.

The common electrode CE may be disposed on a top surface of each of the plurality of light emitting elements LE and a top surface of the fourth organic layer 192. The common electrode CE may be a common layer commonly formed in the first sub-pixel SPX1, the second sub-pixel SPX2, and the third sub-pixel SPX3. The common electrode CE may be made of a transparent conductive material (TCO) such as indium tin oxide (ITO) and/or indium zinc oxide (IZO) that may transmit light.

In one or more embodiments, the pixel electrode PXE (PXE1, PXE2, PXE3) may be referred to as an anode electrode or a first electrode, and the common electrode CE may be referred to as a cathode electrode or a second electrode.

The first capping layer CAP1 may be disposed on the common electrode CE. The first capping layer CAP1 may be formed of an inorganic layer film, for example, a silicon nitride layer, a silicon oxynitride layer, a silicon oxide layer, a titanium oxide layer, and/or an aluminium oxide layer.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be formed by partitioning the light blocking layer BM. Therefore, the first light conversion layer QDL1 is disposed on the first capping layer CAP1 in the first sub-pixel SPX1, and the second light conversion layer QDL2 is disposed on the first capping layer CAP1 in the second sub-pixel SPX2, and a light transmission layer TPL may be disposed on the first capping layer CAP1 in the third sub-pixel SPX3. The light blocking layer BM may overlap the bank layer BNL in the third direction DR3 and may not overlap the plurality of light emitting elements LE.

The first light conversion layer QDL1 may convert a portion of the third light (e.g., light in the blue wavelength band) incident from the light emitting element LE into first light (e.g., light in the red wavelength band). The first light conversion layer QDL1 may include a first base resin BRS1 and first wavelength conversion particles WCP1. The first base resin BRS1 may include a light-transmitting organic material. For example, the first base resin BRS1 may include an epoxy-based resin, an acrylic-based resin, a cardo-based resin, and/or an imide-based resin. The first wavelength conversion particle WCP1 may convert a portion of the third light (e.g., light in the blue wavelength band) incident from the light emitting element LE into first light (e.g., light in the red wavelength band). The first wavelength conversion particle WCP1 may be a quantum dot (QD), a quantum rod, a fluorescent material, and/or a phosphorescent material.

The second light conversion layer QDL2 may convert a portion of the third light (e.g., light in the blue wavelength band) incident from the light emitting element LE into second light (e.g., light in the green wavelength band). It may include a second base resin BRS2 and a second wavelength conversion particle WCP2. The second base resin BRS2 may include a light transmission organic material. For example, the second base resin BRS2 may include an epoxy-based resin, an acrylic-based resin, a cado-based resin, and/or an imide-based resin. The second wavelength conversion particle WCP2 may convert a portion of the third light (e.g., light in the blue wavelength band) incident from the light emitting element LE into second light (e.g., light in the green wavelength band). The second wavelength conversion particle WCP2 may be a quantum dot (QD), a quantum rod, a fluorescent material, and/or a phosphorescent material.

The light transmission layer TPL may include a light transmission organic material. For example, the light transmission layer TPL may include epoxy resin, acrylic resin, cardo resin, and/or imide resin.

The light blocking layer BM may include a first light blocking layer BM1 and a second light blocking layer BM2 that are sequentially stacked. A length in the first direction DR1 or a length in the second direction DR2 of the first light blocking layer BM1 may be wider than a length in the first direction DR1 or a length in the second direction DR2 of the second light blocking layer BM2. The first light blocking layer BM1 and the second light blocking layer BM2 may be formed of an organic layer such as an acrylic resin, an epoxy resin, a phenolic resin, a polyamide resin, a polyimide resin, and/or the like. The first light blocking layer BM1 and the second light blocking layer BM2 may include a light blocking material to prevent light from the light emitting element LE of one sub-pixel from proceeding to the neighboring sub-pixel. For example, the first light blocking layer BM1 and the second light blocking layer BM2 may include an inorganic black pigment such as carbon black and/or an organic black pigment.

The second capping layer CAP2 may be disposed on the first capping layer CAP1 and the light blocking layer BM. The second capping layer CAP2 may be disposed on the side and top surfaces of the light blocking layer BM. That is, the second capping layer CAP2 may be disposed on the side of the first light blocking layer BM1 and on the side and top surfaces of the second light blocking layer BM2.

A reflective layer RF may be disposed between the light blocking layer BM and the first light conversion layer QDL1, between the light blocking layer BM and the second light conversion layer QDL2, and between the light blocking layer BM and the light transmission layer TPL. The reflective layer RF may be disposed on a second capping layer CAP2 disposed on the side of the first light blocking layer BM1 and the side of the second light blocking layer BM2. The reflective layer RF serves to reflect light traveling in the lateral direction from the first light conversion layer QDL1, the second light conversion layer QDL2, and the light transmission layer TPL.

The reflective layer RF may include a highly reflective metal material such as aluminum (AI). The thickness of the reflective layer RF may be approximately 0.1 μm.

Alternatively, the reflective layer RF may include M (where M is an integer greater than or equal to 2) pairs of first and second layers having different refractive indices to act as Distributed Bragg Reflectors (DBR). In this case, M first layers and M second layers may be arranged alternately. The first layer and the second layer may be formed of an inorganic film, for example, a silicon nitride layer, a silicon oxy nitride layer, a silicon oxide layer, a titanium oxide layer, and/or an aluminum oxide layer.

The third capping layer CAP3 may be disposed on the second capping layer CAP2, the first light conversion layer QDL1, the second light conversion layer QDL2, and the light transmission layer TPL. The third capping layer CAP3 may be formed of an inorganic film, for example, a silicon nitride layer, a silicon oxynitride layer, a silicon oxide layer, a titanium oxide layer, and/or an aluminium oxide layer. The first light conversion layer QDL1, the second light conversion layer QDL2, and the light transmission layer TPL may be encapsulated by the first capping layer CAP1, the second capping layer CAP2, and the third capping layer CAP3.

A fifth organic layer 193 may be disposed on the third capping layer CAP3. The fifth organic layer 193 may be formed of acrylic resin, epoxy resin, phenolic resin, polyamide resin, polyimide resin, and/or the like.

A plurality of color filters CF1, CF2, and CF3 may be disposed on the fifth organic layer 193. The plurality of color filters CF1, CF2, and CF3 may include first color filters CF1, second color filters CF2, and third color filters CF3.

The first color filter CF1 disposed in the first sub-pixel SPX1 may transmit the first light (e.g., light in the red wavelength band) and absorb or block the third light (e.g., light in the blue wavelength band). Therefore, the first color filter CF1 may transmit the first light (e.g., light in the red wavelength band) converted by the first light conversion layer QDL1 from among the third light (e.g., light in the blue wavelength band) emitted by the light emitting element LE and absorb or block the third light (e.g., light in the blue wavelength band) not converted by the first light conversion layer QDL1. Thus, the first sub-pixel SPX1 may emit the first light (e.g., light in the red wavelength band).

The second color filter CF2 disposed in the second sub-pixel SPX2 may transmit the second light (e.g., light in the green wavelength band) and absorb or block the third light (e.g., light in the blue wavelength band). Therefore, the second color filter CF2 may transmit the second light (e.g., light in the green wavelength band) converted by the second light conversion layer QDL2 from among the third light (e.g., light in the blue wavelength band) emitted by the light emitting element LE and absorb or block the third light (e.g., light in the blue wavelength band) not converted by the second light conversion layer QDL2. Thus, the second sub-pixel SPX2 may emit the second light (e.g., light in the green wavelength band).

The third color filter CF3 disposed in the third sub-pixel SPX3 may transmit third light (e.g., light in the blue wavelength band). Therefore, the third color filter CF3 may transmit the third light (e.g., light in the blue wavelength band) emitted from the light emitting element LE through the light transmission layer TPL. Accordingly, the third sub-pixel SPX3 may emit the third light (e.g., light in the blue wavelength band).

The first color filter CF1, the second color filter CF2, and the third color filter CF3 overlapping in the third direction DR3 may overlap with the bank layer BNL and the light blocking layer BM in the third direction DR3.

A sixth organic layer 194 for planarization may be disposed on the plurality of color filters CF1, CF2, and CF3. The sixth organic layer 194 may be formed of acrylic resin, epoxy resin, phenolic resin, polyamide resin, polyimide resin, and/or the like.

According to one or more embodiments, a plurality of connection electrodes BE are formed on the bottom of the light emitting element LE, so that the light emitting element LE may be stably connected to the pixel electrode PXE without falling over during the bonding process. Accordingly, the bonding yield of the light emitting element LE may be improved, and color purity and luminance may be improved.

Furthermore, the current spread may be improved by dispersing the contact between the connection electrode BE and the light emitting element LE by distributing the plurality of connection electrodes BE on one surface of the light emitting element LE.

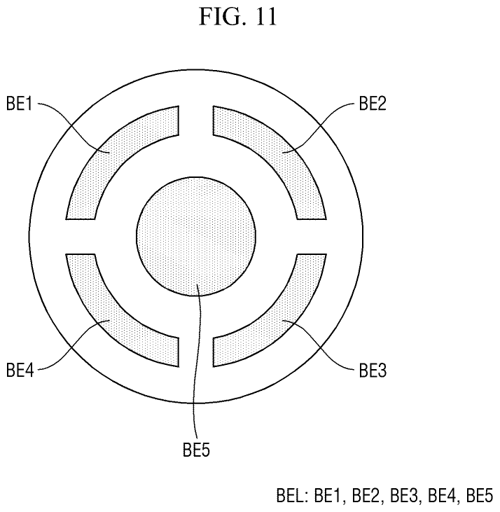

Hereinafter, FIGS. 11-14 are plan views and perspective views of light emitting elements according to one or more embodiments.

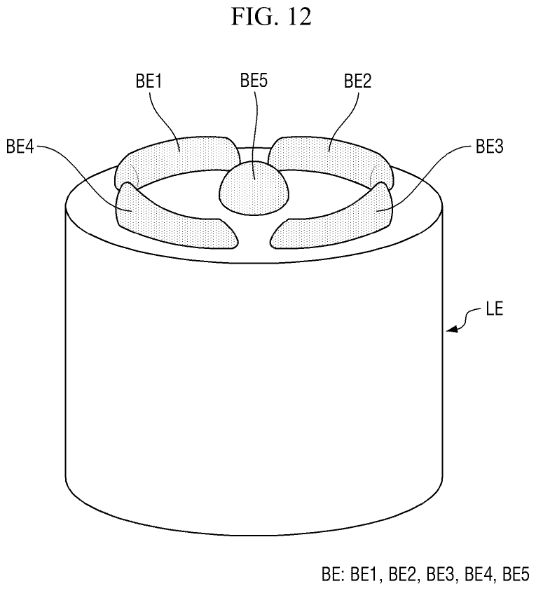

FIG. 11 is a plan view of a light emitting element and a connecting electrode according to one or more embodiments. FIG. 12 is a perspective view of the light emitting element and the connection electrode of FIG. 11.

Referring to FIGS. 11 and 12, a connection electrode layer BEL may include a first connection electrode BE1, a second connection electrode BE2, a third connection electrode BE3, a fourth connection electrode BE4, and a fifth connection electrode BE5. The first connection electrode BE1, the second connection electrode BE2, the third connection electrode BE3, the fourth connection electrode BE4, and the fifth connection electrode BE5 may be arranged to be spaced (e.g., spaced apart) from each other.

The fifth connection electrode BE5 may be disposed at the center of the light emitting element LE. The first connection electrode BE1, the second connection electrode BE2, the third connection electrode BE3, and the fourth connection electrode BE4 may be shaped to be around (e.g., to surround) the fifth connection electrode BE5. The first connection electrode BE1, the second connection electrode BE2, the third connection electrode BE3, and the fourth connection electrode BE4 may be arranged along the same periphery (e.g., circumference). The first connection electrode BE1, the second connection electrode BE2, the third connection electrode BE3, and the fourth connection electrode BE4 may be located inside the edge of the light emitting element LE.

The first connection electrode BE1, the second connection electrode BE2, the third connection electrode BE3, and the fourth connection electrode BE4 may be arranged to be spaced (e.g., spaced apart) from each other at substantially equal or equal intervals. The first connection electrode BE1, the second connection electrode BE2, the third connection electrode BE3, and the fourth connection electrode BE4 may be disposed radially symmetrically to each other. The first connection electrode BE1, the second connection electrode BE2, the third connection electrode BE3, and the fourth connection electrode BE4 may be coaxial with each other, for example, may be arranged along a periphery centered on the fifth connection electrode BE5, but are not limited thereto. The fifth connection electrode BE5 may be a spherical shape or a cylindrical shape but is not limited thereto. The cross-section of the fifth connection electrode BE5 may be not only circular but also polygonal, such as square, pentagon, or hexagon.

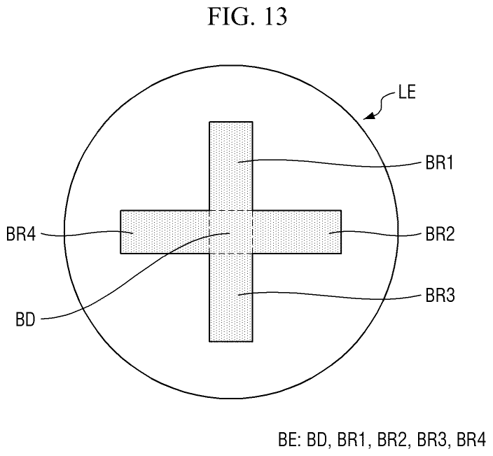

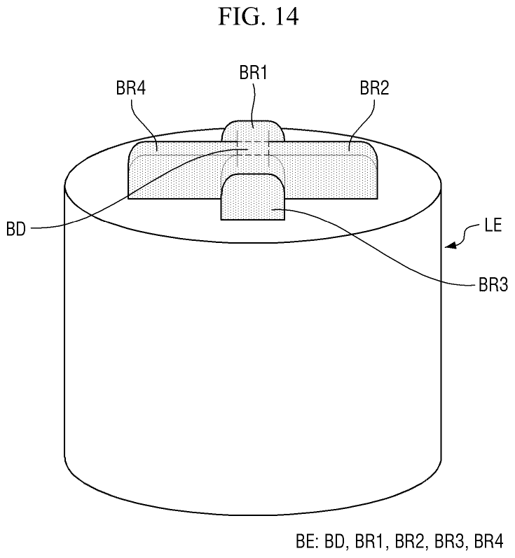

FIG. 13 is a plan view of the light emitting element and connection electrode according to one or more embodiments. FIG. 14 is a perspective view of a light emitting element and the connection electrode of FIG. 13.

Referring to FIGS. 13 and 14, the connection electrode BE may have a cross-shaped structure or a similar structure when viewed from above. The connection electrode BE may include a body portion BD disposed at the center, and a plurality of branch portions BR1, BR2, BR3, and BR4 extending outwardly in, for example, four directions around the body portion BD. For example, the body portion BD may be disposed at a center of the light emitting element LE, and a first branch portion BR1, a second branch portion BR2, a third branch portion BR3, and a fourth branch portion BR4 may extend toward the edge of the light emitting element LE. Each of the plurality of branch portions BR1, BR2, BR3, and BR4 may be disposed in a substantially equal distance or an equal distance from the edge of the light emitting element LE. The body portion BD and the plurality of branch portions BR1, BR2, BR3, and BR4 may be formed integrally.

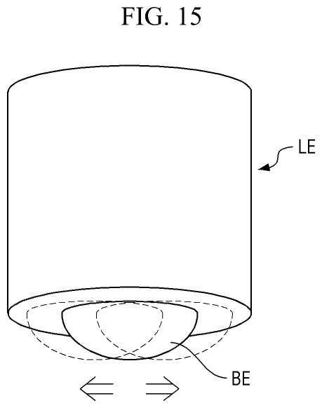

FIG. 15 is a perspective view of a light emitting element and a connection electrode to illustrate a defect that occurs when a single connection electrode is disposed on the light emitting element.

As shown in FIG. 15, when one connection electrode BE is disposed on the light emitting element LE, the probability of the light emitting element LE not falling on the pixel electrodes PXE1, PXE2, and PXE3 increases only when the connection electrode BE is disposed in the center of one side of the light emitting element LE.

In one or more embodiments, if the connection electrode BE is misaligned and is not disposed in the center of the light emitting element LE, the possibility of falling on the pixel electrodes PXE1, PXE2, and PXE3 may increase.

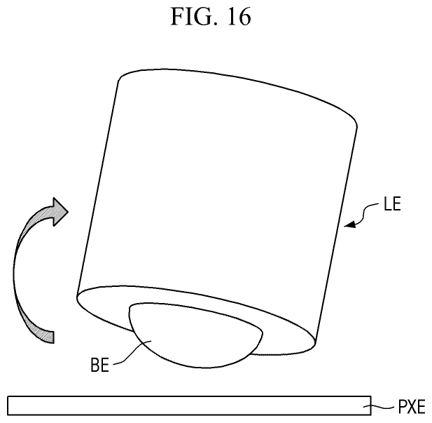

FIG. 16 is a perspective view illustrating a bonding defect of a light emitting element bonded by one connection electrode.

As shown in FIG. 16, the connection electrode BE has a curved top surface due to the nature of the process, so when one connection electrode BE is disposed at the bottom of the light emitting element LE, the light emitting element LE may tip over on the pixel electrodes PXE1, PXE2, and PXE3. Alternatively, the light emitting element LE may be tilted and bonded to the pixel electrodes PXE1, PXE2, and PXE3, thereby reducing light emission efficiency.

In addition, if the connection electrode BE is formed with a central volume, as shown in FIGS. 15 and 16, or if a plurality of relatively small connection electrodes are formed, as shown in the embodiments of FIGS. 7-14, the overall volume of the connection electrode BE may be reduced. Therefore, material saving effects may be expected.

Hereinafter, a manufacturing process of the display device 10 according to one or more embodiments will be described with reference to other drawings.

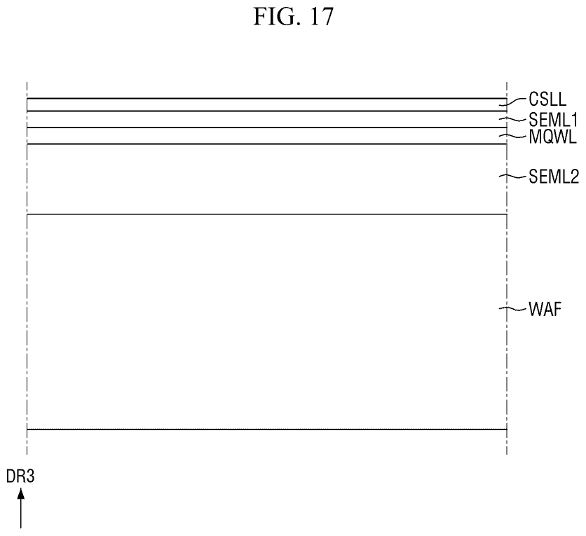

FIGS. 17-29 are diagrams to illustrate a method of manufacturing a display device according to one or more embodiments.

FIGS. 17-29 illustrate the structure according to the formation order of each layer of the display device 10 in cross-sectional views and may generally correspond to the cross-sectional view of FIG. 7. Furthermore, the embodiments of FIGS. 6-10 are illustrated, and the display devices of the embodiments of FIGS. 11-14 may be manufactured by partially changing the manufacturing process. Additionally, the following will focus on the first light emitting area EA1 of the display device 10.

Referring to FIGS. 17-20, a plurality of light emitting elements LE and a connection electrode layer BEL are formed on a base substrate WAF.

Specifically, a base substrate WAF is prepared. The base substrate WAF may be a sapphire substrate (Al₂O₃) or a silicon wafer containing silicon. However, it is not limited thereto, and one or more embodiments will be described by way of example when the base substrate WAF is a sapphire substrate.

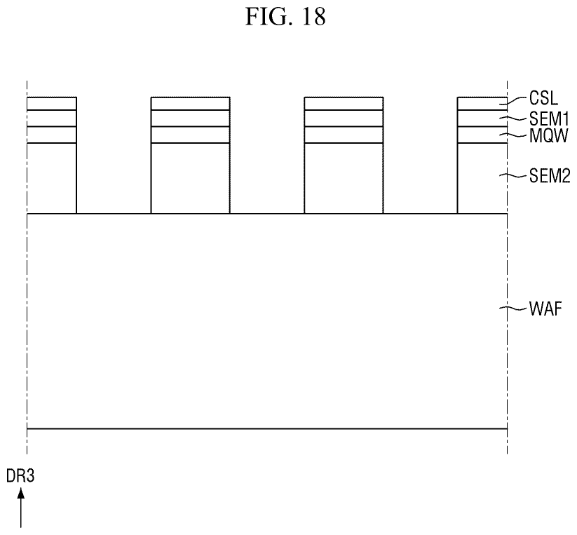

A plurality of semiconductor material layers SEML2, MQWL, and SEML1, and a material layer CSLL for a current spreading layer CSL are formed on the base substrate WAF. In FIGS. 18-28, the electron blocking layer and superlattice layer are omitted. A plurality of semiconductor material layers grown by the epitaxial method may be formed by growing a seed crystal. Here, the method of forming the semiconductor material layer may be electron beam deposition, physical vapour deposition (PVD), chemical vapour deposition (CVD), plasma laser deposition (PLD), dual-type thermal evaporation, sputtering, metal organic chemical vapour deposition (MOCVD), and/or the like, and the semiconductor material layer may be preferably formed by metal organic chemical vapour deposition (MOCVD). However, it is not limited thereto.

The precursor material for forming the plurality of semiconductor material layers is not particularly limited within a range that may be conventionally selected to form the target material. In one example, the precursor material may be a metal precursor containing an alkyl group such as a methyl group and/or an ethyl group. For example, it may be a compound such as trimethyl gallium (Ga(CH₃)₃), trimethyl aluminum (Al(CH₃)₃), and/or triethyl phosphate ((C₂H₅)₃PO₄), but is not limited thereto.

Specifically, the second semiconductor material layer SEML2 is formed on the base substrate WAF. The drawings illustrate that the second semiconductor material layer SEML2 is further stacked, but it is not limited thereto, and a plurality of layers may be formed.

An active material layer MQWL and a first semiconductor material layer SEML1 are sequentially formed on the second semiconductor material layer SEML2 using the above-described method.

Next, the material layer CSLL for the current spreading layer CSL is formed on the first semiconductor material layer SEML1.

Next, referring to FIG. 18, the plurality of semiconductor material layers SEML2, MQWL, and SEML1 and the material layer CSLL for the current spreading layer CSL are etched to form the rod of the light emitting element LE.

The semiconductor material layers SEML2, MQWL, and SEML1 and material layer CSLL for current diffusion layer CSL may be etched by conventional methods. For example, the processes for etching semiconductor material layers SEML2, MQWL, and SEML1 may be dry etching, wet etching, reactive ion etching (RIE), deep reactive ion etching (DRIE), inductively coupled plasma reactive ion etching (ICP-RIE), or the like. In the case of dry etching methods, anisotropic etching is possible and may be suitable for vertical etching. When using the etching method described above, the etching etchant may be Cl₂ and/or O₂. However, it is not limited to this.

Through this process, the rods of a plurality of light emitting elements LE may be obtained. Accordingly, the rods of the plurality of light emitting elements LE are formed including a second semiconductor layer SEM2, an active layer MQW, a first semiconductor layer SEM1, and a current spreading layer CSL.

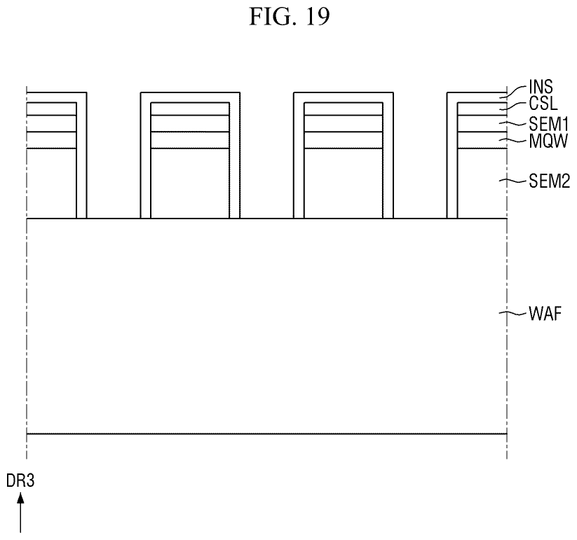

Next, referring to FIG. 19, a protective layer INS is formed to cover the rod of the light emitting element LE (e.g., to cover the outer peripheral or circumferential surface of the rod of the light emitting element LE).

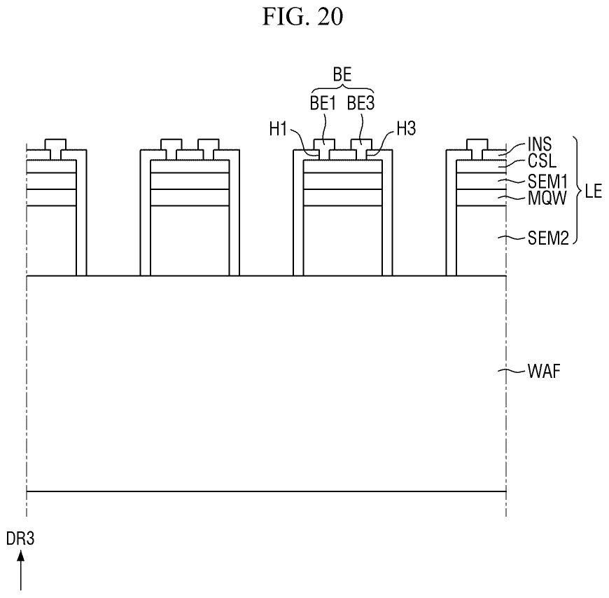

Next, referring to FIG. 20, a plurality of through holes H1 and H3 are formed in the protective layer INS formed on one surface of the rod of the light emitting element LE, and a plurality of connection electrodes BE1 and BE3 are formed.

The protective layer INS exposes the current spreading layer CSL through the plurality of through holes H1 and H3. The connection electrodes BE1 and BE3 may be formed by stacking an electrode material layer on the base substrate WAF and then etching it through an etching process to form a plurality of connection electrodes BE1 and BE3 overlapping the plurality of through holes H1 and H3, but each connection electrode BE1 and BE3 may be formed to be spaced (e.g., spaced apart) from each other.

Accordingly, the plurality of connection electrodes BE1 and BE3 may be formed to cover the current spreading layer CSL exposed by the plurality of through holes H1 and H3. The current spreading layer CSL and the connection electrodes BE1 and BE3 may be in direct contact with each other through the plurality of through holes H1 and H3.

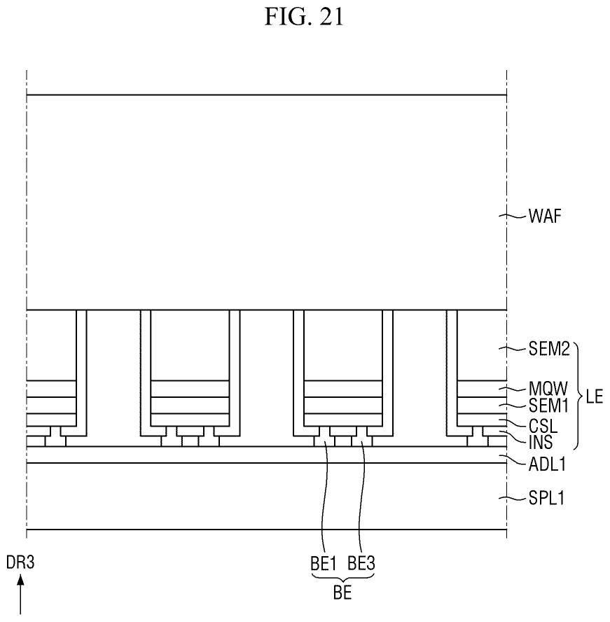

Next, referring to FIG. 21, a first support film SPL1 is attached to the plurality of light emitting elements LE on the base substrate WAF manufactured in FIG. 20. At this time, a first adhesive layer ADL1 may be interposed between the first support film SPL1 and the light emitting element LE.

The first adhesive layer ADL1 may be aligned on the plurality of light emitting elements LE and attached to the plurality of connection electrodes BE1 and BE3 of the plurality of light emitting elements LE. The plurality of light emitting elements LE are arranged in large numbers and may be attached to the first adhesive layer ADL1 without being detached from the base substrate WAF.

The first support film SPL1 may be made of a material that is transparent and mechanically stable to allow light to pass through. For example, the first support film SPL1 may include a transparent polymer such as polyester, polyacrylic, polyepoxy, polyethylene, polystyrene, polyethylene terephthalate, and/or the like. The first adhesive layer ADL1 may include an adhesive material for bonding the light emitting element LE. For example, the adhesive material may include urethane acrylate, epoxy acrylate, polyester acrylate, and/or the like. The adhesive material may be a material whose adhesion changes upon application of ultraviolet (UV) light or heat, thereby facilitating separation of the adhesive layer from the light emitting element LE.

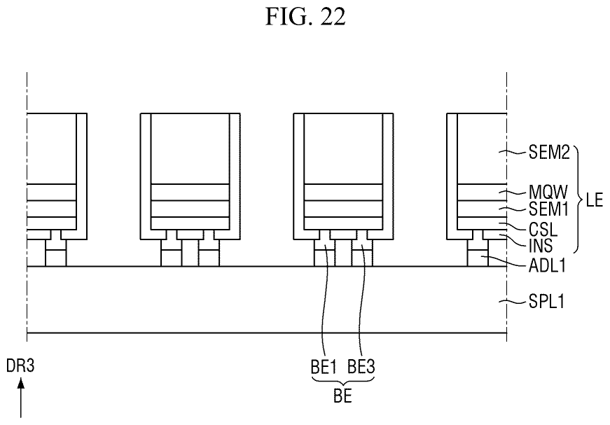

Next, referring to FIGS. 21 and 22, a laser (1^{st} laser) is irradiated to the base substrate WAF to separate the light emitting elements LE from the base substrate WAF. The base substrate WAF is separated from each second semiconductor layer SEM2 of the plurality of light emitting elements LE.

The process for separating the base substrate WAF may be performed by a laser lift off (LLO) process. The laser lift off process utilizes a laser, and a KrF excimer laser (248 nm wavelength) may be used as the source. The energy density of the excimer laser is in the range of about 550 mJ/cm² to 950 mJ/cm², and the incident area may be in the range of 50×50 μm² to 1×1 cm² but is not limited thereto. The base substrate WAF may be separated from the light emitting element LE by irradiating the base substrate WAF with the laser.

Next, referring to FIG. 22, the first adhesive layer ADL1 in the area that does not overlap the light emitting element LE is etched.

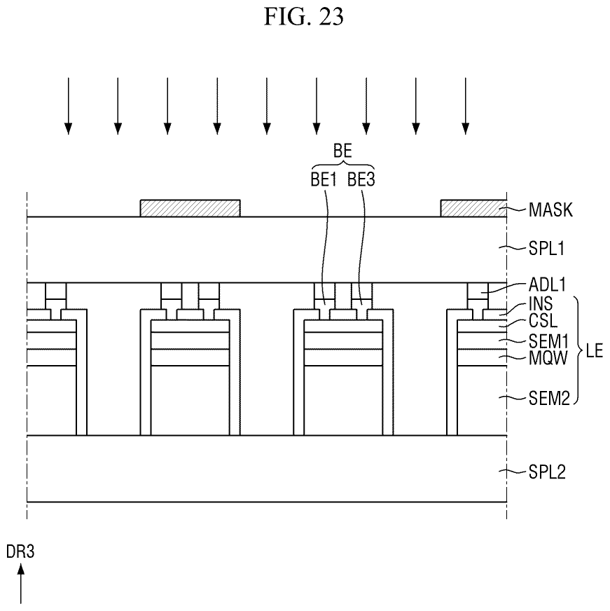

Next, referring to FIG. 23, the first support film SPL1 is aligned on an interposer substrate SPL2. The interposer substrate SPL2 may be composed of a second support layer and a second adhesive layer disposed on the second support layer. The second support layer may be made of a material that is transparent and mechanically stable to allow light to pass through. The second support layer material may be the example materials used in the first support film SPL1. The second adhesive layer may include an adhesive material for bonding the light emitting element LE. As the second adhesive layer material, the example materials used in the first adhesive layer ADL1 may be applied.

Thereafter, the desired light emitting element LE may be selectively transferred to the interposer substrate SPL2 using a mask MASK and a laser. At this time, the first support film SPL1 and the first adhesive layer ADL1 on the plurality of connection electrodes BE1 and BE3 is removed.

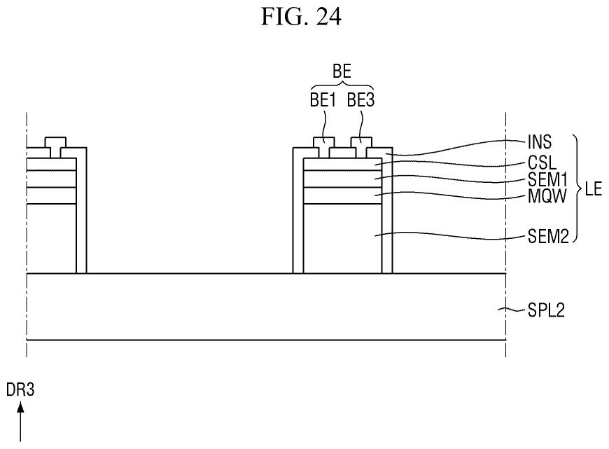

Referring to FIG. 24, the light emitting element LE not covered with a mask MASK was transferred to the interposer substrate SPL2 by a laser.

Through the processes of FIGS. 17-24, the light emitting element LE may be manufactured and transferred to the interposer substrate SPL2.

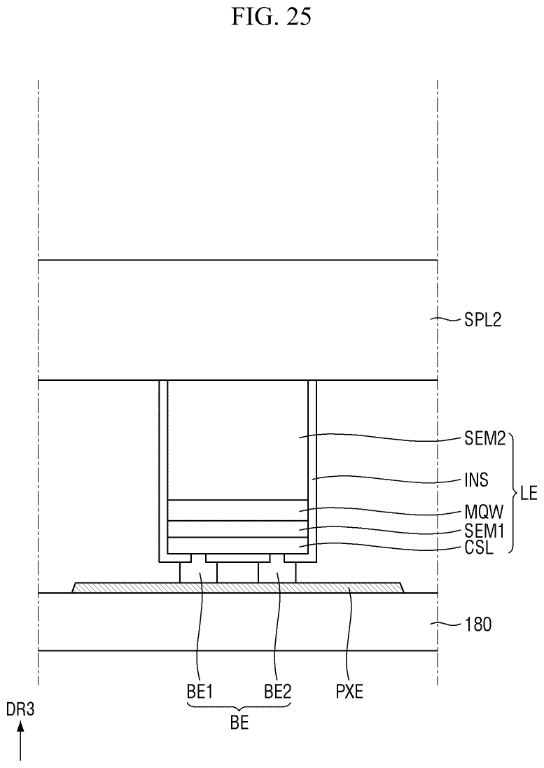

Next, referring to FIG. 25, a substrate SUB on which a bank layer BNL (not illustrated in FIGS. 25-29) and a pixel electrode PXE are disposed is prepared, and the interposer substrate SPL2 is attached to the substrate SUB so that a plurality of connection electrodes BE1 and BE3 connecting to a plurality of light emitting elements LE are in contact with the pixel electrode PXE.

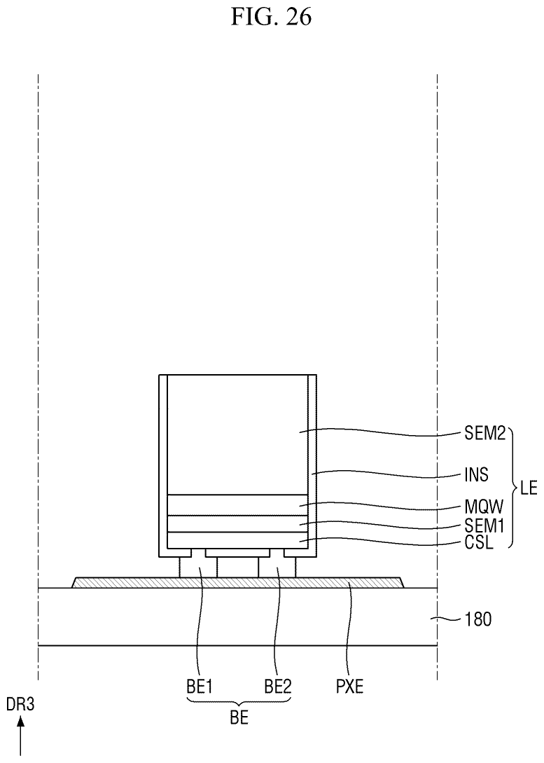

Heat and pressure are applied or a laser is applied to melt the plurality of connection electrodes BE1 and BE3, thereby bonding the pixel electrode PXE and the plurality of light emitting elements LE. Afterwards, the interposer substrate SPL2 is removed as shown in FIG. 26.

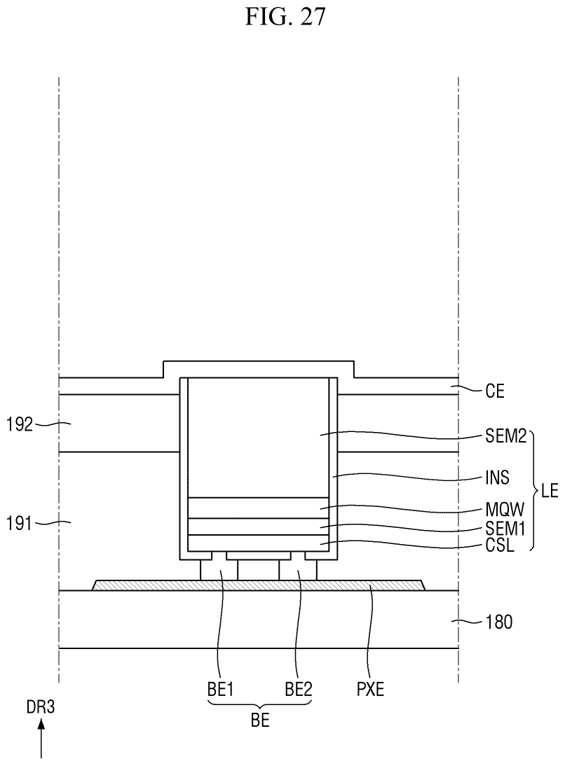

Referring to FIG. 27, organic layers 191 and 192 are formed to flatten the steps caused by the plurality of light emitting elements LE, and a common electrode CE is formed on the organic layers 191 and 192 and the plurality of light emitting elements LE.

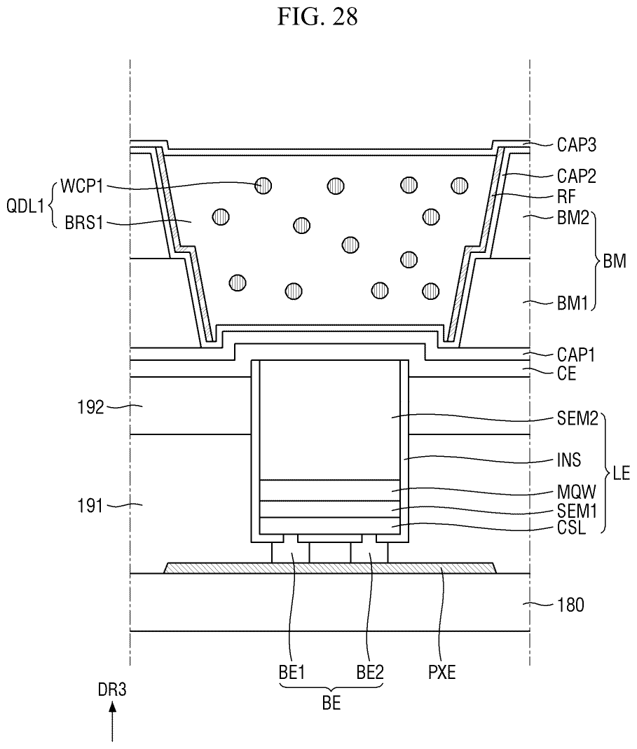

Next, as shown in FIG. 28, a first capping layer CAP1 is formed on the common electrode CE, and then a light blocking layer BM, a second capping layer CAP2, a reflective layer RF, a first light conversion layer QDL1 are successively formed on the first capping layer CAP1. Then, a third capping layer CAP3 is formed on the light blocking layer BM, the reflective layer RF, and the first light conversion layer QDL1.

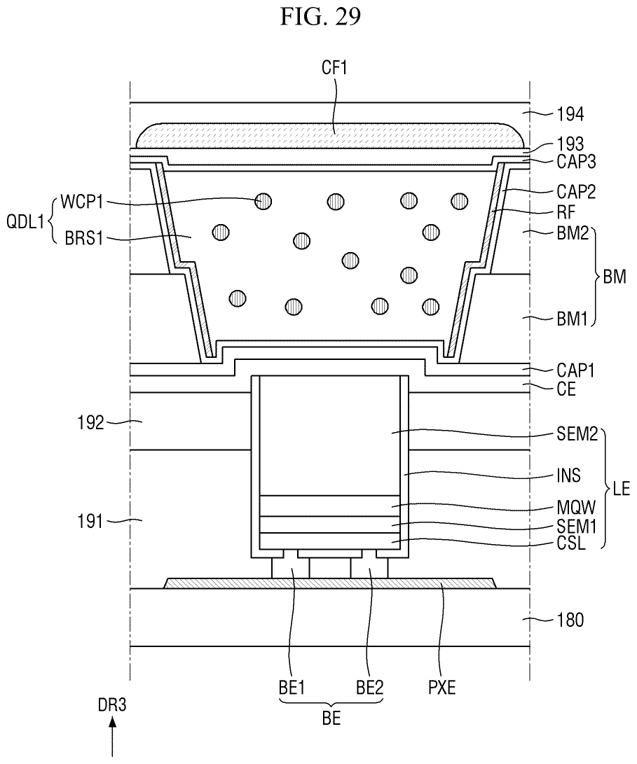

Next, as shown in FIG. 29, the fifth organic layer 193 is formed on a third capping layer CAP3, and a color filter CF1 (e.g., first color filter CF1 in FIG. 29) is formed on the fifth organic layer 193. Afterwards, the sixth organic layer 194 is formed on the first color filter CF1.

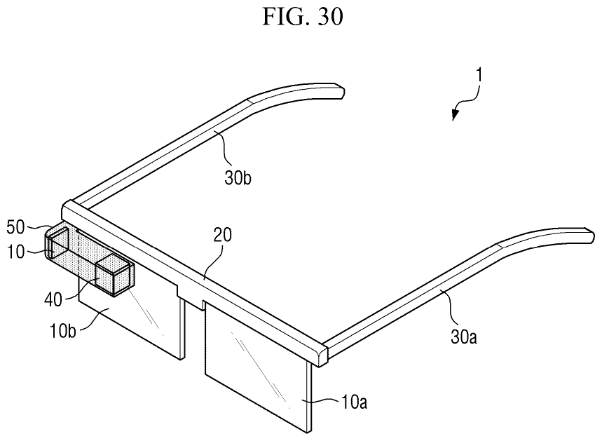

FIG. 30 is an example diagram illustrating a virtual reality device including a display device according to one or more embodiments. FIG. 30 illustrates a virtual reality device 1 in which the display device 10 according to one or more embodiments is used.

Referring to FIG. 30, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 30 illustrates the virtual reality device 1 including the two legs 30a and 30b. However, the present disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 30, and may be applied in various forms and in various electronic devices.

The display device housing 50 may receive the display device 10 and the reflective member 40. An image displayed on the display device 10 may be reflected 1 from the reflective member 40 and provided to a user's right eye through the right-eye lens 10b. Thus, the user may view a virtual reality image displayed on the display device 10 via the right eye.

FIG. 30 illustrates that the display device housing 50 is disposed at a right end of the support frame 20. However, the present disclosure is not limited thereto. For example, the display device housing 50 may be disposed at a left end of the support frame 20. In this case, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be disposed at each of the left end and the right end of the support frame 20. In this case, the user may view the virtual reality image displayed on the display device 10 via both the left eye and the right eye.

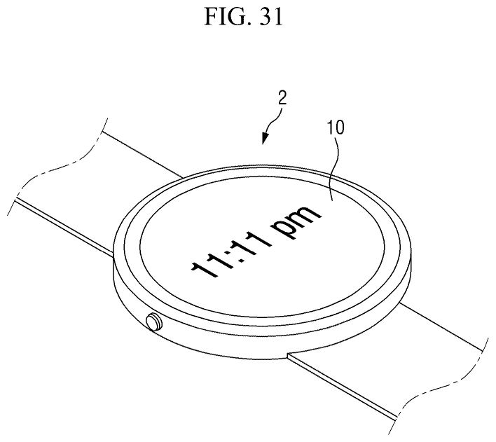

FIG. 31 is an example diagram illustrating a smart device including a display device according to one or more embodiments.

Referring to FIG. 31, a display device 10 according to one or more embodiments may be applied to a smart watch 2 as one of smart devices.

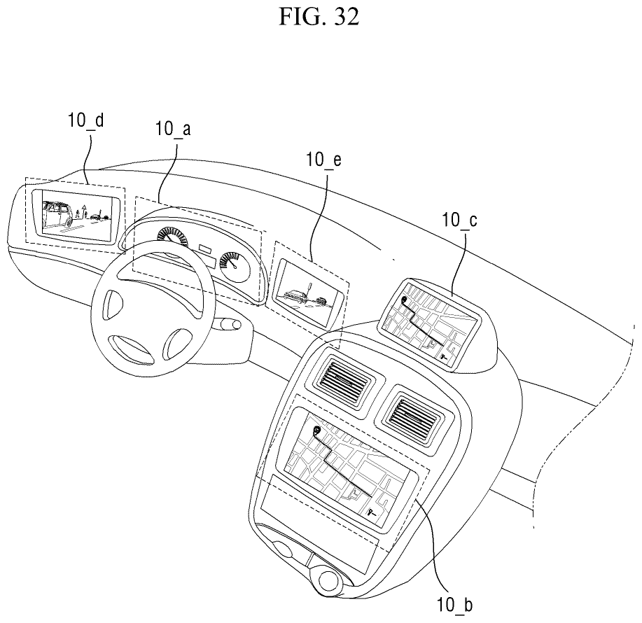

FIG. 32 is an example diagram illustrating a vehicle including a display device according to one or more embodiments. FIG. 32 illustrates a vehicle in which display devices according to one or more embodiments are used.

Referring to FIG. 32, the display devices 10_a, 10_b, and 10_c according to one or more embodiments may be applied to the dashboard of the vehicle, applied to the center fascia of the vehicle, or applied to a Center Information Display (CID) disposed on the dashboard of the vehicle. Further, each of the display devices 10_d and 10_e according to one or more embodiments may be applied to each room mirror display that replaces each of side-view mirrors of the vehicle.

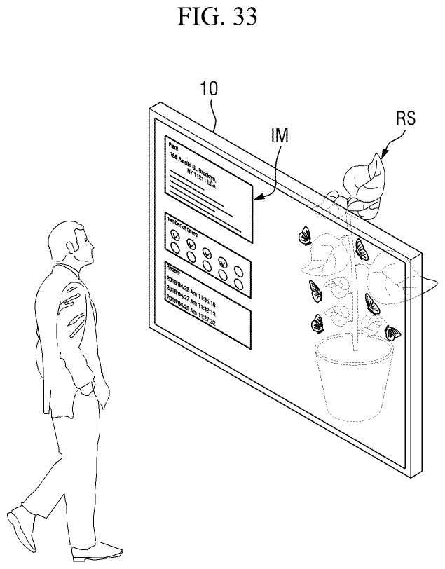

FIG. 33 is an example diagram illustrating a transparent display device including a display device according to one or more embodiments.

Referring to FIG. 33, a display device according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the substrate SUB of the display device 10 shown in FIG. 7 may include a light transmitting portion that may transmit light therethrough or may be made of a material that may transmit light therethrough.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a substrate on which a pixel electrode is provided;
a light emitting element on the pixel electrode; and
a plurality of connection electrodes between the pixel electrode and the light emitting element, the plurality of connection electrodes being spaced from each other.

2. The display device of claim 1, wherein each of the plurality of connection electrodes contacts the light emitting element at different points.

3. The display device of claim 1, wherein the light emitting element comprises a protective layer having a plurality of through-holes, on at least one side of the light emitting element,
wherein the plurality of connection electrodes contacts the light emitting element through the plurality of through-holes.

4. The display device of claim 3, wherein a width of a through-hole from among the plurality of through-holes is less than or equal to a width of a connection electrode from among the plurality of connection electrodes.

5. The display device of claim 1, wherein the plurality of connection electrodes is spaced from an edge of the light emitting element.

6. The display device of claim 1, wherein the plurality of connection electrodes has a circular or polygonal cross-section.

7. The display device of claim 1, wherein the plurality of connection electrodes comprises a first connection electrode, a second connection electrode, a third connection electrode, and a fourth connection electrode,
wherein the first connection electrode, the second connection electrode, the third connection electrode, and the fourth connection electrode are arranged to be radially symmetrical to each other.

8. The display device of claim 7, wherein the plurality of connection electrodes further comprises a fifth connection electrode,
wherein the first connection electrode, the second connection electrode, the third connection electrode, and the fourth connection electrode are arranged along a periphery centered on the fifth connection electrode.

9. The display device of claim 1, wherein each of the plurality of connection electrodes comprises a reflective portion in contact with the light emitting element, and a connection portion on one surface of the reflective portion,
wherein the reflective portion comprises a metal having a reflectivity that is higher than a reflectivity of the connection portion.

10. The display device of claim 1, wherein the light emitting element comprises a current spreading layer, a first semiconductor layer, an active layer, and a second semiconductor layer,
wherein the current spreading layer, the first semiconductor layer, the active layer, and the second semiconductor layer are sequentially stacked, and the current spreading layer is closer to a connection electrode from among the plurality of connection electrodes than the first semiconductor layer is.

11. The display device of claim 1, further comprising a common electrode on the light emitting element.

12. A display device comprising:
a substrate on which a pixel electrode is provided;
a light emitting element on the pixel electrode; and
a connection electrode between the pixel electrode and the light emitting element, the connection electrode having a body portion at a center and a plurality of branch portions extending outward from the body portion.

13. The display device of claim 12, wherein the body portion and the plurality of branch portions are integrated.

14. The display device of claim 12, wherein the light emitting element comprises a protective layer having a through-hole, on at least one side of the light emitting element,
wherein the connection electrode contacts the light emitting element through the through-hole.

15. The display device of claim 14, wherein a width of the through-hole is less than or equal to a width of the connection electrode.

16. The display device of claim 12, wherein the plurality of branch portions is spaced from an edge of the light emitting element.

17. The display device of claim 12, wherein the plurality of branch portions comprises a first branch portion, a second branch portion, a third branch portion, and a fourth branch portion, and the plurality of branch portions extends in four directions.

18. The display device of claim 12, wherein the connection electrode comprise a reflective portion in contact with the light emitting element, and a connection portion on one surface of the reflective portion,
wherein the reflective portion comprises a metal having a reflectivity that is higher than a reflectivity of the connection portion.

19. The display device of claim 12, wherein the light emitting element comprises a current spreading layer, a first semiconductor layer, an active layer, and a second semiconductor layer,
wherein the current spreading layer, the first semiconductor layer, the active layer, and the second semiconductor layer are sequentially stacked, and the current spreading layer is closer to the connection electrode than the first semiconductor layer.

20. The display device of claim 12, further comprising a common electrode on the light emitting element.
